(19) United States
(12) Patent Application Publication
(10) Pub. No.: US 2026/0353950 A1
(43) Pub. Date: Nov. 5, 2026

(54) DISPLAY DEVICE AND ELECTRONIC DEVICE INCLUDING THE SAME

(71) Applicant: Samsung Display Co., Ltd., Yongin-Si (KR)

(72) Inventors: Yunmi Kim, Yongin-si (KR); Donghee Shin, Yongin-si (KR); Hyeongseok Kim, Yongin-si (KR); Doyeong Park, Yongin-si (KR)

(21) Appl. No.: 19/535,274

(22) Filed: Feb. 10, 2026

(30) Foreign Application Priority Data
May 2, 2025 (KR) 10-2025-0058489

(51) Int. Cl. H10K 59/131

(52) U.S. Cl. CPC H10K 59/131

(57) ABSTRACT

Provided is a display device including a substrate including a display area and a non-display area, a first, a second, a third, and a fourth sub-pixel circuit disposed sequentially in a first direction on the substrate and each including a driving transistor and a switching transistor, a first insulating layer covering the first to fourth sub-pixel circuits, a plurality of pixel electrodes spaced apart from each other on the first insulating layer, and a plurality of emission layers disposed on the pixel electrodes, respectively, in the display area, wherein the first sub-pixel circuit is not electrically connected to each of the pixel electrodes, and the fourth sub-pixel circuit is electrically connected to one of the pixel electrodes.

### CROSS-REFERENCE TO RELATED APPLICATION

This application is based on and claims priority, under 35 U.S.C. §119, to Korean Patent Application No. 10-2025-0058489 filed on May 2, 2025 in the Korean Intellectual Property Office, the disclosure of which is incorporated by reference herein in its entirety.

### BACKGROUND

### 1. Field

One or more embodiments relate to devices, and more particularly, to a display device and an electronic device.

### 2. Description of the Related Art

Portable electronic devices are widely used today. Tablet personal computers (PCs) have recently been used as portable electronic devices in addition to compact electronic devices, such as mobile phones.

In order to support various functions, such portable electronic devices include display devices to provide users with visual information, such as images or video. As other components for driving display devices have been miniaturized, the proportion occupied by display devices in electronic devices gradually increases, and structures that can be bent from a flat state have been developed.

### SUMMARY

One or more embodiments include a display device with improved freedom in the arrangement of an emission layer at the boundary between a round display area and a non-display area in a vertical fusion pixel (VFP) structure.

However, the above benefit is merely an example, and there may be other benefits.

Additional aspects will be set forth in part in the description which follows and, in part, will be apparent from the description, or may be learned by practice of the presented embodiments of the disclosure.

According to one or more embodiments, a display device includes a substrate including a display area and a non-display area, a first, a second, a third, and a fourth sub-pixel circuit disposed sequentially in a first direction on the substrate and each including a driving transistor and a switching transistor, a first insulating layer covering the first to fourth sub-pixel circuits, a plurality of pixel electrodes spaced apart from each other on the first insulating layer, and a plurality of emission layers disposed on the pixel electrodes, respectively, in the display area, wherein the first sub-pixel circuit is not electrically connected to each of the pixel electrodes, and the fourth sub-pixel circuit is electrically connected to one of the pixel electrodes.

In an embodiment, at least a portion of the first sub-pixel circuit may overlap the non-display area and at least a portion of the fourth sub-pixel circuit may overlap the display area.

In an embodiment, the second sub-pixel circuit and the fourth sub-pixel circuit may be configured to receive data signals for light of a same color.

In an embodiment, the first sub-pixel circuit, the second sub-pixel circuit, and the third sub-pixel circuit may be configured to receive data signals for light of different colors.

In an embodiment, the display device may further include a plurality of connection electrodes disposed on the first insulating layer and respectively electrically connected to the first to fourth sub-pixel circuits, wherein an upper surface of a connection electrode electrically connected to the sub-pixel circuit is sealed by the first insulating layer, and a connection electrode electrically connected to the fourth sub-pixel circuit is electrically connected to one of the pixel electrodes.

In an embodiment, the display device may further include a common electrode disposed on the emission layers, wherein the common electrode overlaps each of the first to fourth sub-pixel circuits.

In an embodiment, the display device may further include a fifth sub-pixel circuit, a sixth sub-pixel circuit, a seventh sub-pixel circuit, and an eighth sub-pixel circuit disposed sequentially in the first direction from the fourth sub-pixel circuit on the substrate, each including a driving transistor and a switching transistor, wherein each of the fifth sub-pixel circuit, the sixth sub-pixel circuit, the seventh sub-pixel circuit, and the eighth sub-pixel circuit is electrically connected to a corresponding one of the pixel electrodes and a corresponding one of the emission layers.

In an embodiment, the first sub-pixel circuit and the seventh sub-pixel circuit may be configured to receive data signals for light of a same color, the second sub-pixel circuit, the fourth sub-pixel circuit, the sixth sub-pixel circuit, and the eighth sub-pixel circuit may be configured to receive data signals for light of a same color, the third sub-pixel circuit and the fifth sub-pixel circuit may be configured to receive data signals for light of a same color, and the first sub-pixel circuit, the second sub-pixel circuit, and the third sub-pixel circuit may be configured to receive data signals for light of different colors.

In an embodiment, emission layers respectively electrically connected to the first, second, third, fourth, fifth, sixth, seventh, and eighth sub-pixel circuits may be disposed in a PenTile structure.

In an embodiment, in a plan view, at least a portion of a boundary line between the display area and the non-display area may have a curved shape.

According to one or more embodiments, an electronic device includes a substrate including a display area and a non-display area, a first, a second, a third, a fourth, a fifth, a sixth, a seventh, and an eighth sub-pixel circuit disposed sequentially in a first direction on the substrate and each including a driving transistor and a switching transistor, a first insulating layer covering the first, the second, the third, the fourth, the fifth, the sixth, the seventh, and the eighth sub-pixel circuits, a plurality of pixel electrodes spaced apart from each other on the first insulating layer, and a plurality of emission layers disposed on the pixel electrodes, respectively, in the display area, wherein the first sub-pixel circuit is not electrically connected to each of the pixel electrodes, the eighth sub-pixel circuit is electrically connected to any one of the pixel electrodes, and the second sub-pixel circuit, the fourth sub-pixel circuit, the sixth sub-pixel circuit, and the eighth sub-pixel circuit are configured to receive data signals for light of a same color.

In an embodiment, each of the second sub-pixel circuit, the fourth sub-pixel circuit, the sixth sub-pixel circuit, and the eighth sub-pixel circuit may be configured to receive a data signal for red light.

In an embodiment, the first sub-pixel circuit and the seventh sub-pixel circuit may be configured to receive data signals for light of a same color, and the third sub-pixel circuit and the fifth sub-pixel circuit may be configured to receive data signals for light of a same color.

In an embodiment, each of the first sub-pixel circuit and the seventh sub-pixel circuit may be configured to receive a data signal for red light, and each of the third sub-pixel circuit and the fifth sub-pixel circuit may be configured to receive a data signal for blue light.

In an embodiment, the first sub-pixel circuit, the second sub-pixel circuit, and the third sub-pixel circuit may be configured to receive data signals for light of different colors.

In an embodiment, emission layers respectively electrically connected to the first, second, third, fourth, fifth, sixth, seventh, and eighth sub-pixel circuits may be disposed in a PenTile structure.

In an embodiment, at least a portion of the first sub-pixel circuit may overlap the non-display area and at least a portion of the eighth sub-pixel circuit may overlap the display area.

In an embodiment, the electronic device may further include a plurality of connection electrodes disposed on the first insulating layer and respectively electrically connected to the first, second, third, fourth, fifth, sixth, seventh, and eighth sub-pixel circuits.

In an embodiment, an upper surface of a connection electrode electrically connected to the sub-pixel circuit may be sealed by the first insulating layer, and a connection electrode electrically connected to the eighth sub-pixel circuit may be electrically connected to any one of the pixel electrodes.

In an embodiment, the display device may further include a common electrode disposed on the emission layers, wherein the common electrode overlaps each of the first to eighth sub-pixel circuits.

In an embodiment, in a plan view, at least a portion of a boundary line between the display area and the non-display area may have a curved shape.

Other aspects, features and advantages other than those described above would become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are plan views schematically illustrating a display device according to an embodiment;

FIG. 3 is an equivalent circuit diagram of a pixel disposed in a display area of the display device of FIG. 2;

FIG. 4 is a cross-sectional view schematically illustrating a display device according to an embodiment;

FIGS. 5 - 9 are plan views schematically illustrating a display device according to an embodiment;

FIGS. 10 - 12 are plan views schematically illustrating a display device according to an embodiment;

FIG. 13 is a cross-sectional view schematically illustrating a display device according to an embodiment;

FIG. 14 is a block diagram of an electronic device according to an embodiment; and

FIG. 15 is schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b, or c" indicates only a, only b, only c, both a and b, both a and c, both b and c, all of a, b, and c, or variations thereof.

The disclosure can undergo various modifications and have various embodiments, and certain embodiments are illustrated in the drawings and described in detail in the detailed description. The effects and features of the disclosure and a method for achieving them would become clear with reference to embodiments described in detail below together with the drawings. However, the disclosure is not limited to the embodiments disclosed below and may be implemented in various forms.

Hereinafter, embodiments are described in detail with reference to the accompanying drawings. When describing with reference to the drawings, identical or corresponding components are given the same drawing reference numerals and redundant descriptions thereof are omitted.

In the embodiments below, the terms "first," "second," etc. are not used in a limiting sense but are used for the purpose of distinguishing one component from another component.

In the embodiments below, singular expressions include plural expressions unless the context clearly indicates otherwise.

In the embodiments below, terms such as "include" or "have" mean that a feature or component described in the specification is present, and do not exclude in advance the possibility that one or more other features or components may be added.

In the following embodiments, when a part, such as a film, region, component, etc., is described to be on or above another part, it includes not only a case where it is directly on top of the other part, but also a case where another film, region, component, etc. is located therebetween.

In the drawings, the sizes of components may be exaggerated or reduced for convenience of explanation. For example, the size and thickness of each component shown in the drawing are arbitrarily shown for convenience of explanation, and thus the disclosure is not necessarily limited to what is shown.

In the embodiments below, the x-axis, y-axis, and z-axis are not limited to three axes on an orthogonal coordinate system, and can be interpreted in a broad sense that includes them. For example, the x-axis, y-axis, and z-axis may be orthogonal to each other, but they can also refer to different directions that are not orthogonal to each other.

In some embodiments, where the implementation is otherwise feasible, specific process sequences may be performed in a different order than that described. For example, two processes described sequentially may be performed substantially simultaneously, or may proceed in the reverse order from what is described.

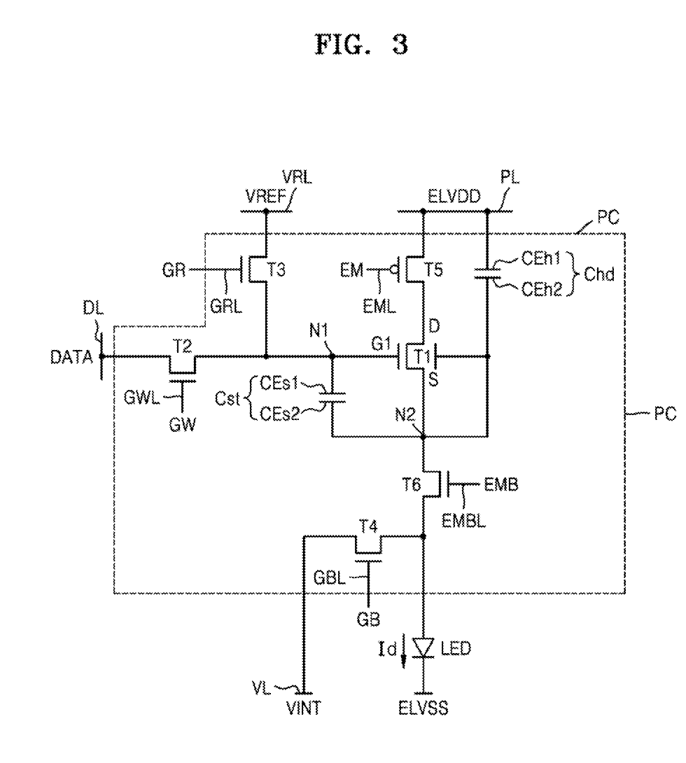

In this specification, "in a plan view" means a plane viewed in a direction perpendicular to a substrate 100 (e.g., in FIG. 2). That is, "A and B are mutually spaced apart in a plan view" means "A and B are mutually spaced apart when viewed in a direction perpendicular to the substrate 100 (e.g., in FIG. 2)."

In this specification, "in a cross-sectional view" indicates a plane cut in a direction perpendicular to the substrate 100 (see FIG. 2). That is, "A and B are mutually spaced apart in a cross-sectional view" indicates "A and B are mutually spaced apart in the plane cut in the direction perpendicular to the substrate 100 (see FIG. 2)."

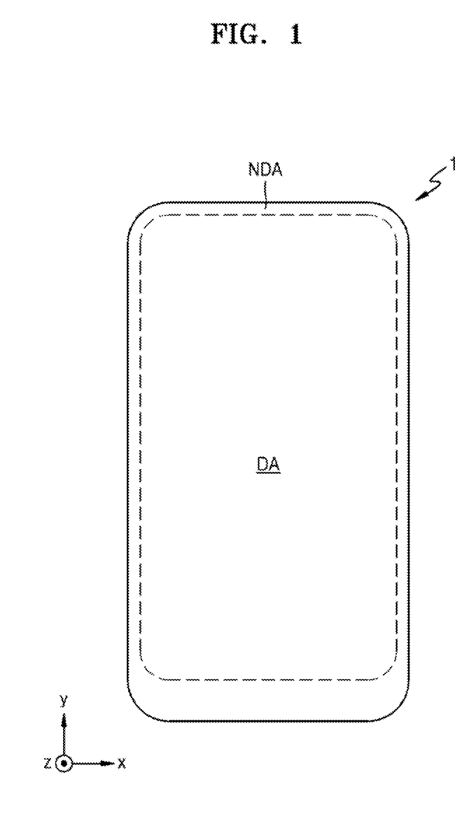

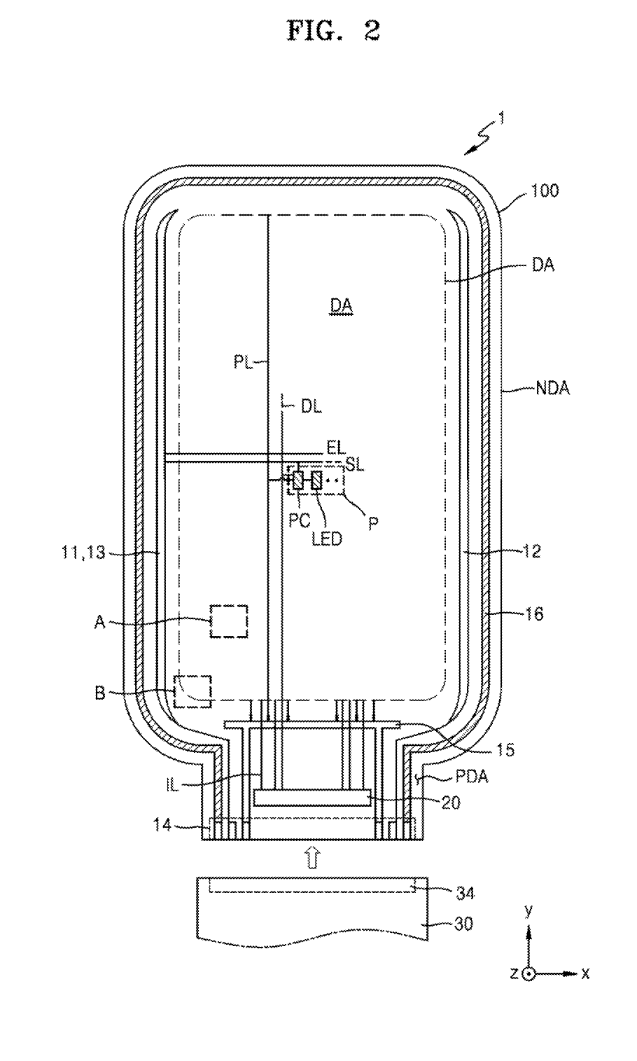

FIGS. 1 and 2 are plan views schematically illustrating a display device 1 according to an embodiment.

Referring to FIG. 1, the display device 1 may include a display area DA and a non-display area NDA outside (or at the periphery) the display area DA. Because the display device 1 includes a substrate 100, it may be understood that the substrate 100 includes the display area DA and the non-display area NDA. Alternatively, it may be understood that the display area DA and the non-display area NDA are defined on the substrate 100.

The display area DA is a portion on which images are displayed, and a plurality of pixels P may be disposed therein. The display area DA may have various shapes, such as a circle, an ellipse, a polygon, or a shape of a specific figure. In FIG. 1, it is shown by way of example that the display area DA has an approximately rectangular shape with round corners. The non-display area NDA may be disposed outside the display area DA. The non-display area NDA may be disposed to surround at least a portion of the display area DA. An emission layer 220 may not be disposed in the non-display area NDA.

Hereinafter, an organic light-emitting display device will be used as an example for describing the display device 1 according to an embodiment, but the display device of the disclosure is not limited thereto. In another embodiment, the display device 1 of the disclosure may be an inorganic light-emitting display (or inorganic electroluminescent (EL) display) or a display device such as a quantum dot light-emitting display. For example, an emission layer of a display element provided in the display device 1 may include an organic material, an inorganic material, quantum dots, an organic material and quantum dots, or an inorganic material and quantum dots.

The substrate 100 included in the display device 1 may include glass, ceramic, metal, or polymer resin. The substrate 100 may include, for example, a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layer structure including two layers containing such polymer resin and an inorganic layer located between the layers. Alternatively, the substrate 100 may have a structure in which layers including such polymer resin and inorganic layers are laminated alternately. The inorganic layer may include, for example, silicon oxide, silicon nitride, or silicon oxynitride.

The pixels P may be disposed in the display area DA, and the display area DA may provide an image by using light emitted from the pixels P. Each of the pixels P may include a plurality of light-emitting diodes LED, and the light-emitting diodes LED may be electrically connected to a sub-pixel circuit PC. The sub-pixel circuit PC and the light-emitting diode LED may be disposed in the display area DA. In FIG. 1, for convenience, the sub-pixel circuit PC and the light-emitting diode LED are shown as being located side by side, but in reality, the sub-pixel circuit PC and the light-emitting diode LED may overlap at least partially. For example, the light-emitting diode LED may be disposed on the sub-pixel circuit PC.

A gate driving circuit, a pad 14, a first power supply wiring 15, and a second power supply wiring 16 may be disposed in the non-display area NDA. The gate driving circuit may include, for example, a first scan driving circuit 11, a second scan driving circuit 12, and/or an emission control driving circuit 13.

The first scan driving circuit 11 may provide a scan signal to the sub-pixel circuit PC through a gate line SL. The second scan driving circuit 12 may be disposed opposite the first scan driving circuit 11 with the display area DA therebetween. A portion of the sub-pixel circuits PC disposed in the display area DA may be electrically connected to the first scan driving circuit 11, and the remaining portion thereof may be connected to the second scan driving circuit 12. However, in some cases, the second scan driving circuit 12 may be omitted.

The emission control driving circuit 13 may be disposed on one side of the display area DA, similar to the first scan driving circuit 11. The emission control driving circuit 13 may provide an emission control signal to the pixel P through an emission control line EL. In FIG. 2, the emission control driving circuit 13 is shown as being disposed only on one side of the display area DA, but the disclosure is not limited thereto. For example, the display device 1 may have emission control driving circuits 13 disposed along two sides of the display area DA. Alternatively, the first scan driving circuit 11 may be disposed on one side of the display area DA, and the emission control driving circuit 13 may be disposed on the other side thereof.

The pad 14 may be disposed in a pad area PDA of the non-display area NDA. The pad 14 may be exposed and not covered by an insulating layer, and may be electrically connected to a display circuit board 30. The pad 14 of the display circuit board 30 may be electrically connected to the pad 14 of the display device 1.

The display circuit board 30 may transmit signals or power from a control unit to the display device 1. A control signal generated by the control unit may be transmitted to each gate driving circuit through the display circuit board 30. In addition, the control unit may provide a first power supply voltage ELVDD (see FIG. 3) and a second power supply voltage ELVSS (see FIG. 3) to the first power supply wiring 15 and the second power supply wiring 16. The first power supply voltage ELVDD (see FIG. 3) (hereinafter referred to as "driving voltage") may be provided to each sub-pixel circuit PC through a driving voltage line PL connected to the first power supply wiring 15, and the second power supply voltage ELVSS (see FIG. 3) (hereinafter referred to as "common voltage") may be provided to a common electrode of the light-emitting diode LED connected to the second power supply wiring 16. The first power supply wiring 15 may extend in a first direction (x-axis direction). The second power supply wiring 16 may have a loop shape with one end open and may partially surround the display area DA.

A data signal of a data driver 20 may be transmitted to the sub-pixel circuit PC through a data line DL, which is electrically connected to an input line IL via the input line IL.

FIG. 3 is an equivalent circuit diagram of a pixel P disposed in the display area DA of the display device 1 of FIG. 2.

Referring to FIG. 3, the sub-pixel circuit PC connected to the light-emitting diode LED may include a plurality of transistors and at least one capacitor. For example, the sub-pixel circuit PC may include at least one driving transistor, at least one switching transistor, and at least one capacitor. For example, the sub-pixel circuit PC may include a first transistor T1, a second transistor T2, a third transistor T3, a fourth transistor T4, a fifth transistor T5, a sixth transistor T6, a storage capacitor Cst, and a hold capacitor Chd.

The first transistor T1 may be a driving transistor configured to output a driving current corresponding to a data signal, and the second transistor T2, the third transistor T3, the fourth transistor T4, the fifth transistor T5, and the sixth transistor T6 may be switching transistors configured to transmit signals through on/off. A first terminal (first electrode) of each of the first transistor T1, the second transistor T2, the third transistor T3, the fourth transistor T4, the fifth transistor T5, and the sixth transistor T6 may be either a source region or a drain region, and a second terminal (second electrode) may be the other region.

At least one of the first transistor T1, the second transistor T2, the third transistor T3, the fourth transistor T4, the fifth transistor T5, and the sixth transistor T6 may be a p-channel metal-oxide-semiconductor field-effect transistor (MOSFET) (PMOS), and the rest may be n-channel MOSFETs (NMOSs). For example, the fifth transistor T5 may be a PMOS, and the first transistor T1, the second transistor T2, the third transistor T3, the fourth transistor T4, and the sixth transistor T6 may be NMOSs. Alternatively, the fifth transistor T5 and sixth transistor T6 may be PMOSs, and the first transistor T1, the second transistor T2, the third transistor T3, and the fourth transistor T4 may be NMOSs. Alternatively, all transistors may be NMOSs, or all transistors may be PMOSs.

At least one of the transistors may be a transistor having a low-temperature polycrystalline silicon (LTPS) semiconductor layer, and the rest may be transistors having oxide semiconductor layers. For example, the fifth transistor T5 may include a semiconductor layer including polycrystalline silicon having high reliability, and each of the remaining transistors may include an oxide semiconductor layer having the characteristics of high carrier mobility and low leakage current. Below, a case is described below in which the fifth transistor T5 is a PMOS including a silicon semiconductor layer, and the remaining transistors are NMOSs including oxide semiconductor layers.

The sub-pixel circuit PC may be electrically connected to gate lines configured to respectively transmit signals to the gate electrodes of the transistors. For example, the sub-pixel circuit PC may be connected to a scan line GWL configured to transmit a scan signal GW, an initialization gate line GBL configured to transmit an initialization signal GB, a reference gate line GRL configured to transmit a reference signal GR, a first emission control line EML configured to transmit a first emission control signal EM, a second emission control line EMBL configured to transmit a second emission control signal EMB, and the data line DL configured to transmit a data signal DATA. In addition, the sub-pixel circuit PC may be connected to the driving voltage line PL configured to transmit the driving voltage ELVDD, a reference voltage line VRL configured to transmit a reference voltage VREF, and an initialization voltage line VL configured to transmit an initialization voltage VINT.

The first transistor T1, which is a driving transistor, may be electrically connected between the driving voltage line PL and a second node N2. The first transistor T1 may include a first gate electrode G1 connected to a first node N1, a first terminal electrically connected to the driving voltage line PL, and a second terminal connected to the second node N2. The first terminal may be a drain region D and the second terminal may be a source region S. The first terminal of the first transistor T1 may be electrically connected to the driving voltage line PL via the fifth transistor T5, and the second terminal of the first transistor T1 may be electrically connected to a pixel electrode of the light-emitting diode LED. The first transistor T1 may receive the data signal DATA according to a switching operation of the second transistor T2 and control the amount of driving current I_{d} flowing to the light-emitting diode LED.

The second transistor T2, which is a data write transistor, may be electrically connected between the data line DL and the first node N1. The second transistor T2 may include a gate electrode connected to the scan line GWL, a first terminal connected to the data line DL, and a second terminal connected to the first node N1. The second transistor T2 may be turned on by the scan signal GW received via the scan line GWL and may electrically connect the data line DL to the first node N1 so that the data signal DATA from the data line DL may be transmitted to the first node N1.

The third transistor T3, which is a first initialization transistor, may be electrically connected between the first node N1 and the reference voltage line VRL. The third transistor T3 may include a gate electrode connected to the reference gate line GRL, a first terminal connected to the first node N1, and a second terminal connected to the reference voltage line VRL. The third transistor T3 may be turned on by the reference signal GR received via the reference gate line GRL so that the reference voltage VREF from the reference voltage line VRL may be transmitted to the first node N1.

The fourth transistor T4, which is a second initialization transistor, may be electrically connected between the first transistor T1 and the initialization voltage line VL. The fourth transistor T4 may include a gate electrode connected to the initialization gate line GBL, a first terminal connected to a second terminal of the sixth transistor T6 and to the light-emitting diode LED, and a second terminal connected to the initialization voltage line VL. The fourth transistor T4 may turned on by the initialization signal GB received via the initialization gate line GBL so that the initialization voltage VINT from the initialization voltage line VL may be transmitted to the pixel electrode of the light-emitting diode LED. That is, the fourth transistor T4 may initialize a potential of the pixel electrode of the light-emitting diode LED to the initialization voltage VINT.

The fifth transistor T5, which is an emission control transistor, may be electrically connected between the driving voltage line PL and the first transistor T1. The fifth transistor T5 may include a gate electrode connected to the first emission control line EML, a first terminal connected to the driving voltage line PL, and a second terminal connected to the first terminal of the first transistor T1. The fifth transistor T5 may be turned on or off depending on the first emission control signal EM from the first emission control line EML.

The sixth transistor T6, which is an operation control transistor, may be connected between the first transistor T1 and the light-emitting diode LED. The sixth transistor T6 may include a gate electrode connected to the second emission control line EMBL, a first terminal connected to the second node N2, and a second terminal connected to the light-emitting diode LED. The sixth transistor T6 may turned on by the second emission control signal EMB from the second emission control line EMBL and may electrically connect the second node N2 to the pixel electrode of the light-emitting diode LED.

In FIG. 3, the fifth transistor T5 operates in response to the first emission control signal EM and the sixth transistor T6 operates in response to the second emission control signal EMB, but the disclosure is not limited thereto. For example, the fifth transistor T5 and the sixth transistor T6 may operate in response to the same emission control signal.

The reference signal GR may be substantially synchronized with the scan signal GW of the sub-pixel circuit PC located in the previous row. The initialization signal GB may be substantially synchronized with the scan signal GW. Alternatively, the initialization signal GB may be substantially synchronized with the scan signal GW or the reference signal GR of the sub-pixel circuit PC located in the next row.

The storage capacitor Cst may be electrically connected between the first node N1 and the second node N2. That is, the sub-pixel circuit PC included in a display panel according to the present embodiment may be of a source follower-type circuit in which the storage capacitor Cst is connected between the first node N1 and the second node N2. A first storage electrode CEs1 of the storage capacitor Cst may be connected to the first node N1, and a second storage electrode CEs2 may be connected to the second node N2. The storage capacitor Cst may store a threshold voltage of the first transistor T1 and a voltage corresponding to the data signal DATA.

The hold capacitor Chd may be connected between the driving voltage line PL and the second node N2. A first hold electrode CEh1 of the hold capacitor Chd may be electrically connected to the driving voltage line PL, and a second hold electrode CEh2 may be electrically connected to the second node N2. The hold capacitor Chd may ensure that the voltage of the second node N2 of the first transistor T1 does not fluctuate and has a constant voltage when a surrounding signal fluctuates.

The light-emitting diode LED may include a pixel electrode electrically connected to the second node N2 and a common electrode above the pixel electrode, and the common electrode may receive the common voltage ELVSS. The common electrode may be integral to the plurality of light-emitting diodes LED.

In FIG. 3, the sub-pixel circuit PC includes six transistors and two capacitors, but the disclosure is not limited thereto. For example, the sub-pixel circuit PC may include five transistors and two capacitors. The sub-pixel circuit PC may include seven transistors and one capacitor.

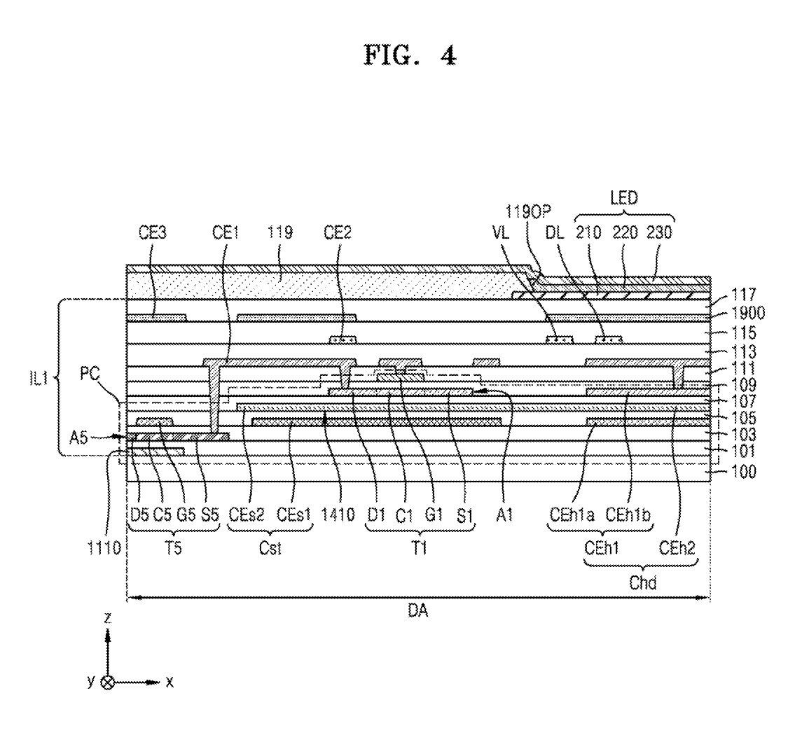

FIG. 4 is a cross-sectional view schematically illustrating the display device 1 according to an embodiment.

Specifically, FIG. 4 is a cross-sectional view of the display device 1 in the display area DA.

Referring to FIG. 4, the display device 1 may include the sub-pixel circuit PC including transistors and capacitors disposed on the substrate 100, a first insulating layer IL1 covering the sub-pixel circuit PC, and the light-emitting diode LED electrically connected to the sub-pixel circuit PC. Additionally, the display device 1 may include a plurality of connection electrodes CE1, CE2, and CE3, which are disposed in the first insulating layer IL1 and are electrically connected to the sub-pixel circuit PC.

FIG. 4 shows the first transistor T1, the fifth transistor T5, the storage capacitor Cst, and the hold capacitor Chd. In addition, FIG. 4 shows that the first insulating layer IL1 includes a buffer layer 101, a first gate insulating layer 103, a second gate insulating layer 105, a first interlayer insulating layer 107, a third gate insulating layer 109, a second interlayer insulating layer 111, a first organic insulating layer 113, a second organic insulating layer 115, and a third organic insulating layer 117.

A lower metal layer 1110 may be disposed on the substrate 100. The lower metal layer 1110 may include one or more materials selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu). For example, the lower metal layer 1110 may have a single-layer structure including Mo, a double-layer structure in which a Mo layer and a Ti layer are laminated, or a triple-layer structure in which a Ti layer, an Al layer, and a Ti layer are laminated.

The lower metal layer 1110 may have a constant voltage level. For example, the lower metal layer 1110 may have the same voltage level as the driving voltage line PL described above with reference to FIG. 3. That is, the driving voltage ELVDD may be applied to the lower metal layer 1110. To this end, the lower metal layer 1110 may be electrically connected, for example, to a portion of the driving voltage line PL or to the first power supply wiring 15 in the non-display area NDA. The lower metal layer 1110 may at least partially shield light traveling to a fifth semiconductor layer A5 of the fifth transistor T5 and may protect the fifth transistor T5 from electrostatic discharge (ESD).

The buffer layer 101 may be disposed on the lower metal layer 1110 to cover the lower metal layer 1110. The buffer layer 101 may be an inorganic insulating layer including an inorganic insulating material, such as silicon oxide, silicon nitride, and/or silicon oxynitride. The buffer layer 101 may have a single- or a multi-layer structure.

A silicon semiconductor layer may be disposed on the buffer layer 101. In FIG. 4, the fifth transistor T5 is shown as including the silicon semiconductor layer. That is, in FIG. 4, the fifth semiconductor layer A5 included in the fifth transistor T5 is shown as being located on the buffer layer 101. The fifth semiconductor layer A5 may include a channel region C5 and doped regions S5 and D5 doped with impurities and respectively disposed on opposite sides of the channel region C5. One of the doped regions S5 and D5 of the fifth semiconductor layer A5 may be the source region and the other one may be the drain region.

The first gate insulating layer 103 may be disposed on the fifth semiconductor layer A5 to cover the fifth semiconductor layer A5. The first gate insulating layer 103 may be an inorganic insulating layer including an inorganic insulating material, such as silicon oxide, silicon nitride, and/or silicon oxynitride. The first gate insulating layer 103 may have a single- or a multi-layer structure.

A fifth gate electrode G5 may be disposed on the first gate insulating layer 103. The fifth gate electrode G5 may overlap the channel region C5 of the fifth semiconductor layer A5. In addition to the fifth gate electrode G5, the first storage electrode CEs1 of the storage capacitor Cst and a sub-layer of the first hold electrode CEh1 of the hold capacitor Chd, for example, the first lower hold electrode CEh1a, may be disposed on the first gate insulating layer 103.

The fifth gate electrode G5, the first storage electrode CEs1 of the storage capacitor Cst, and the first lower hold electrode CEh1a of the hold capacitor Chd may include the same material. The fifth gate electrode G5, the first storage electrode CEs1 of the storage capacitor Cst, and the first lower hold electrode CEh1a of the hold capacitor Chd may include Al, Pt, Pd, Ag, Mg, Au, Ni, Nd, Ir, Cr, Li, Ca, Mo, Ti, W, and/or Cu, and may have a single- or a multi-layer structure including these materials. For example, the fifth gate electrode G5, the first storage electrode CEs1 of the storage capacitor Cst, and the first lower hold electrode CEh1a of the hold capacitor Chd may have a single-layer structure including Mo or a multi-layer structure of Mo/Al/Mo.

The second gate insulating layer 105 may be disposed on the fifth gate electrode G5, the first storage electrode CEs1 of the storage capacitor Cst, and the first lower hold electrode CEh1a of the hold capacitor Chd to cover them. The second gate insulating layer 105 may be an inorganic insulating layer including an inorganic insulating material, such as silicon oxide, silicon nitride, and/or silicon oxynitride. The second gate insulating layer 105 may have a single- or a multi-layer structure. When desired, the second gate insulating layer 105 may include a material that is different from a material of the first gate insulating layer 103. For example, the first gate insulating layer 103 may include silicon oxide and the second gate insulating layer 105 may include silicon nitride.

A conductive layer 1410 (hereinafter referred to as "fifth conductive layer" for convenience) may be disposed on the second gate insulating layer 105. The fifth conductive layer 1410 may overlap the first storage electrode CEs1 of the storage capacitor Cst and the first lower hold electrode CEh1a of the hold capacitor Chd. The fifth conductive layer 1410 may include the second storage electrode CEs2 of the storage capacitor Cst and the second hold electrode CEh2 of the hold capacitor Chd. That is, a portion of the fifth conductive layer 1410 may be the second storage electrode CEs2 of the storage capacitor Cst, and another portion of the fifth conductive layer 1410 may be the second hold electrode CEh2 of the hold capacitor Chd. In this way, the second storage electrode CEs2 of the storage capacitor Cst and the second hold electrode CEh2 of the hold capacitor Chd may be integrally provided as a single body.

The fifth conductive layer 1410 may include Al, Pt, Pd, Ag, Mg, Au, Ni, Nd, Ir, Cr, Li, Ca, Mo, Ti, W, and/or Cu, and may have a single- or a multi-layer structure including these materials. For example, the fifth conductive layer 1410 may have a single-layer structure including Mo, or a multi-layer structure of Mo/Al/Mo.

The first interlayer insulating layer 107 may be disposed on the fifth conductive layer 1410 to cover the fifth conductive layer 1410. The first interlayer insulating layer 107 may be an inorganic insulating layer including an inorganic insulating material, such as silicon oxide, silicon nitride, and/or silicon oxynitride. The first interlayer insulating layer 107 may have a single- or a multi-layer structure. For example, the first interlayer insulating layer 107 may have a laminated structure of a layer including silicon oxide and a layer including silicon nitride.

A first semiconductor layer A1 of the first transistor T1 and a first upper hold electrode CEh1b of the hold capacitor Chd may be disposed on the first interlayer insulating layer 107. The first semiconductor layer A1 of the first transistor T1 and the first upper hold electrode CEh1b of the hold capacitor Chd may include the same material. Specifically, the first semiconductor layer A1 of the first transistor T1 and the first upper hold electrode CEh1b of the hold capacitor Chd may include an oxide semiconductor. The oxide semiconductor may be an oxide semiconductor including at least one element selected from the group consisting of indium (In), gallium (Ga), tin (Sn), zirconium (Zr), vanadium (V), hafnium (Hf), cadmium (Cd), germanium (Ge), Cr, Ti, Al, cesium (Cs), cerium (Ce), and zinc (Zn). For example, the oxide semiconductor may include InSnZnO (ITZO) or InGaZnO (IGZO).

The first semiconductor layer A1 may include a channel region C1 and conductive doped regions S1 and D1 disposed on opposite sides of the channel region C1. One of the doped regions S1 and D1 may be the source region and the other one may be the drain region. The first semiconductor layer A1 may be disposed on a layer that is different from a layer on which the fifth semiconductor layer A5 described above is disposed. A vertical distance from the substrate 100 to the first semiconductor layer A1 may be greater than a vertical distance from the substrate 100 to the fifth semiconductor layer A5.

The first upper hold electrode CEh1b of the hold capacitor Chd may overlap the fifth conductive layer 1410 and the first lower hold electrode CEh1a of the hold capacitor Chd under the fifth conductive layer 1410. The first upper hold electrode CEh1b of the hold capacitor Chd may be electrically connected to the first lower hold electrode CEh1a.

The third gate insulating layer 109 may be disposed on the first semiconductor layer A1 and the first upper hold electrode CEh1b of the hold capacitor Chd to cover them. The third gate insulating layer 109 may be an inorganic insulating layer including an inorganic insulating material, such as silicon oxide, silicon nitride, and/or silicon oxynitride. The third gate insulating layer 109 may have a single- or a multi-layer structure. For example, the third gate insulating layer 109 may have a single-layer structure including silicon oxide.

Although FIG. 4 shows that the third gate insulating layer 109 passes through a side surface of the first semiconductor layer A1 and contacts an upper surface of the first interlayer insulating layer 107, the disclosure is not limited thereto. For example, the third gate insulating layer 109 may have substantially a same pattern and/or a same width as the first gate electrode G1 described below. That is, after forming an insulating layer for forming the third gate insulating layer 109 and forming a conductive layer for forming the first gate electrode G1 on this insulating layer, the insulating layer and the conductive layer may be simultaneously patterned into the same shape to form the third gate insulating layer 109 and the first gate electrode G1. In this case, the third gate insulating layer 109 may not be in contact with the upper surface of the first interlayer insulating layer 107.

The first gate electrode G1 may be disposed on the third gate insulating layer 109. The first gate electrode G1 may overlap the channel region C1 of the first semiconductor layer A1. The first gate electrode G1 may include Al, Pt, Pd, Ag, Mg, Au, Ni, Nd, Ir, Cr, Li, Ca, Mo, Ti, W, and/or Cu, and may have a single- or a multi-layer structure including these materials. For example, the first gate electrode G1 may have a three-layer structure of Ti layer/Al layer/Ti layer.

The second interlayer insulating layer 111 may be disposed on the first gate electrode G1 to cover the first gate electrode G1. The second interlayer insulating layer 111 may be an inorganic insulating layer including an inorganic insulating material, such as silicon oxide, silicon nitride, and/or silicon oxynitride. The second interlayer insulating layer 111 may have a single- or a multi-layer structure. For example, the second interlayer insulating layer 111 may have a laminated structure of a layer including silicon oxide and a layer including silicon oxynitride.

A first connection electrode CE1 may be disposed on the second interlayer insulating layer 111. The first connection electrode CE1 may be electrically connected to the sub-pixel circuit PC. The first connection electrode CE1 may be electrically connected to at least one of the first transistor T1, the fifth transistor T5, and the hold capacitor Chd. The first connection electrode CE1 may include Al, Pt, Pd, Ag, Mg, Au, Ni, Nd, Ir, Cr, Li, Ca, Mo, Ti, W, and/or Cu, and may have a single- or a multi-layer structure including these materials. For example, the first connection electrode CE1 may have a three-layer structure of Ti layer/Al layer/Ti layer.

The first organic insulating layer 113 may be disposed on the first connection electrode CE1 to cover them. The first organic insulating layer 113 may include an organic insulating material, such as acryl, benzocyclobutene (BCB), polyimide, or hexamethyldisiloxane (HMDSO).

A second connection electrode CE2 electrically connected to the data line DL, the initialization voltage line VL, and the first connection electrode CE1 may be disposed on the first organic insulating layer 113. The data line DL, the initialization voltage line VL, and the second connection electrode CE2 may include Al, Pt, Pd, Ag, Mg, Au, Ni, Nd, Ir, Cr, Li, Ca, Mo, Ti, W, and/or Cu, and may have a single- or a multi-layer structure including these materials. For example, the data line DL, the initialization voltage line VL, and the second connection electrode CE2 may have a three-layer structure of Ti layer/Al layer/Ti layer.

The second organic insulating layer 115 may be disposed on the data line DL, the initialization voltage line VL, and the second connection electrode CE2 to cover them. The second organic insulating layer 115 may include an organic insulating material, such as acryl, BCB, polyimide, or HMDSO.

A third connection electrode CE3 electrically connected to a voltage layer 1900 and the second connection electrode CE2 may be disposed on the second organic insulating layer 115. The voltage layer 1900 may have a voltage level of the driving voltage line PL. The voltage layer 1900 and the second connection electrode CE2 may include Al, Pt, Pd, Ag, Mg, Au, Ni, Nd, Ir, Cr, Li, Ca, Mo, Ti, W, and/or Cu, and may have a single- or a multi-layer structure including these materials. For example, the voltage layer 1900 and the second connection electrode CE2 may have a three-layer structure of Ti layer/Al layer/Ti layer.

The third organic insulating layer 117 may be disposed on the voltage layer 1900 and the second connection electrode CE2 to cover the voltage layer 1900 and the second connection electrode CE2. The third organic insulating layer 117 may include an organic insulating material, such as acryl, BCB, polyimide, or HMDSO.

The light-emitting diode LED may be disposed on the third organic insulating layer 117. The light-emitting diode LED may include a pixel electrode 210, the emission layer 220, and a common electrode 230 on the third organic insulating layer 117.

The pixel electrode 210 may be a (semi-)transparent electrode or a reflective electrode. For example, the pixel electrode 210 may include a reflective layer including Ag, Mg, Al, Pt, Pd, Au, Ni, Nd, Ir, Cr or a compound thereof, and a transparent or semi-transparent electrode layer located on the reflective layer. The transparent or semi-transparent electrode layer may include at least one selected from the group consisting of indium tin oxide (ITO), indium zinc oxide (IZO), zinc oxide (ZnOₓ: ZnO or ZnO₂), indium oxide (In₂O₃), indium gallium oxide (IGO), and aluminum zinc oxide (AZO). For example, the pixel electrode 210 may have a three-layer structure of ITO/Ag/ITO.

A bank layer 119 may be disposed on the third organic insulating layer 117. The bank layer 119 may cover an edge of the pixel electrode 210 and increase a distance between the pixel electrode 210 and the common electrode 230, thereby preventing arcing or the like from occurring at the edge of the pixel electrode 210. That is, the bank layer 119 may have an opening 119OP to expose a central portion of the pixel electrode 210. The bank layer 119 may be formed by a method such as spin coating and may include one or more organic insulating materials selected from the group consisting of polyimide, polyamide, acrylic resin, BCB, and phenol resin.

At least a portion of the emission layer 220 of the light-emitting diode LED may be disposed within the opening 119OP defined in the bank layer 119. An emission area of the light-emitting diode LED may be defined by the opening 119OP. The emission layer 220 may include an organic material including a fluorescent or phosphorescent material which emits red light, green light, blue light, or white light. The emission layer 220 may be a low-molecular organic material or a high-molecular organic material, and functional layers, such as a hole transport layer (HTL), a hole injection layer (HIL), an electron transport layer (ETL), and an electron injection layer (EIL), may be selectively disposed under and over the emission layer 220.

The common electrode 230 may be a light-transmitting electrode or a reflective electrode. For example, the common electrode 230 may be a transparent or semi-transparent electrode and may include a thin-film of a metal having a low work function, such as Li, Ca, Al, Ag, Mg, or a compound thereof (e.g., lithium fluoride (LiF)). In addition, the common electrode 230 may further include a transparent conductive oxide (TCO) film including ITO, IZO, ZnO, ZnO₂, or In₂O₃, located on the metal thin-film.

The common electrode 230 may be integrally formed as a single body across an entire surface of the display area DA to cover the display area DA, and may be disposed over the emission layer 220 and the bank layer 119. That is, the pixel electrodes 210 may be disposed to correspond to the light-emitting diodes LED, respectively, and the common electrode 230 may be integrally formed as a single body to correspond to a plurality of light-emitting diodes LED. The plurality of light-emitting diodes LED may share the common electrode 230, and a laminated structure of the pixel electrode 210, the emission layer 220, and the common electrode 230 may correspond to the light-emitting diode LED.

When desired, an encapsulation layer may be disposed on the light-emitting diode LED. The encapsulation layer may include a first inorganic encapsulation layer, a second inorganic encapsulation layer, and an organic encapsulation layer therebetween.

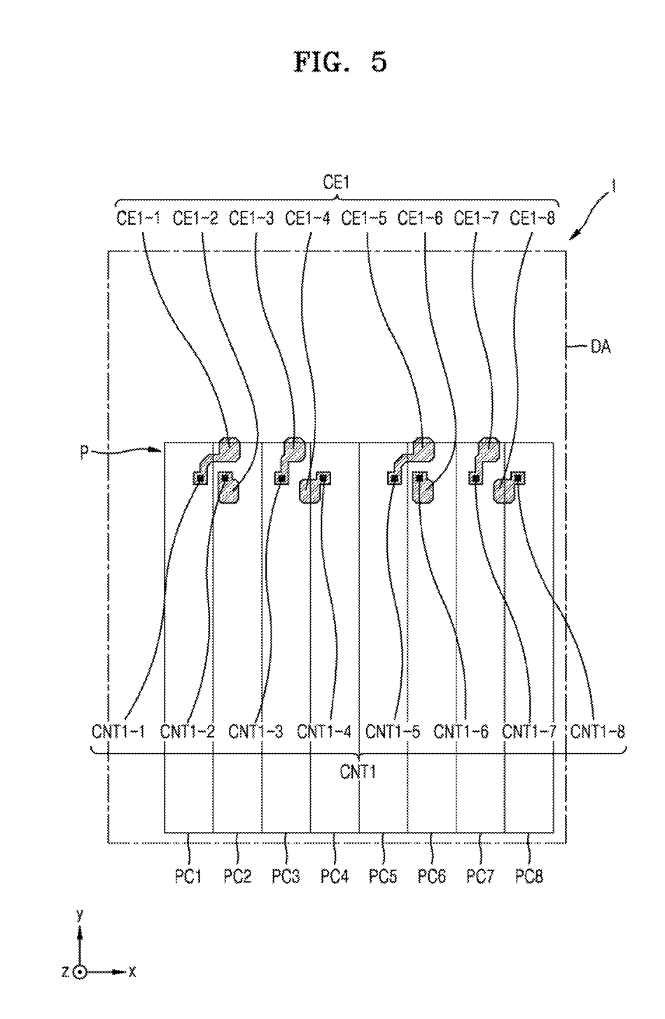

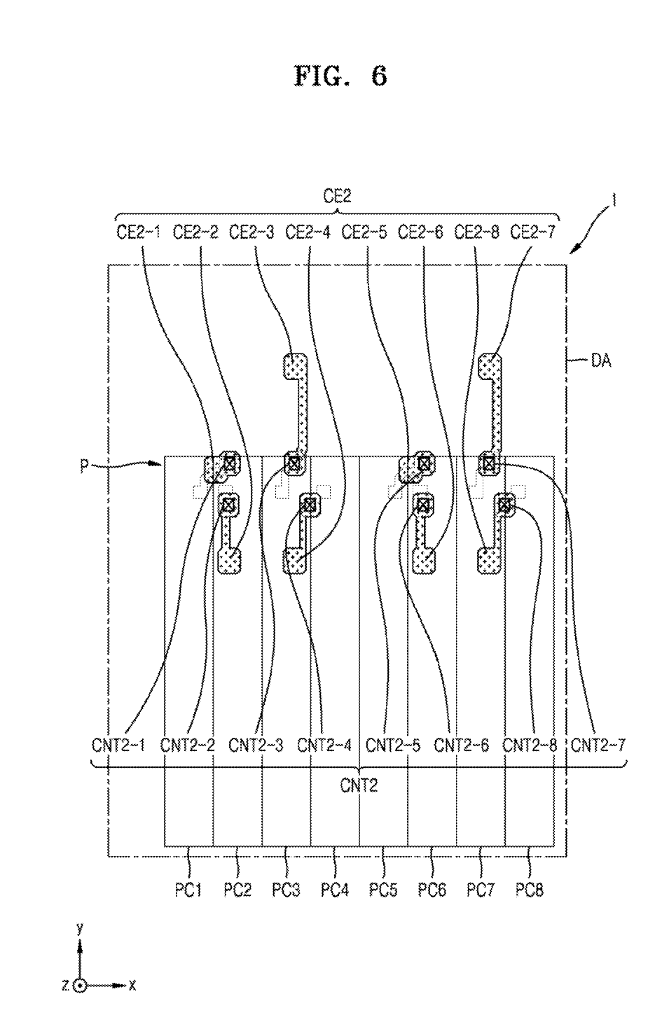

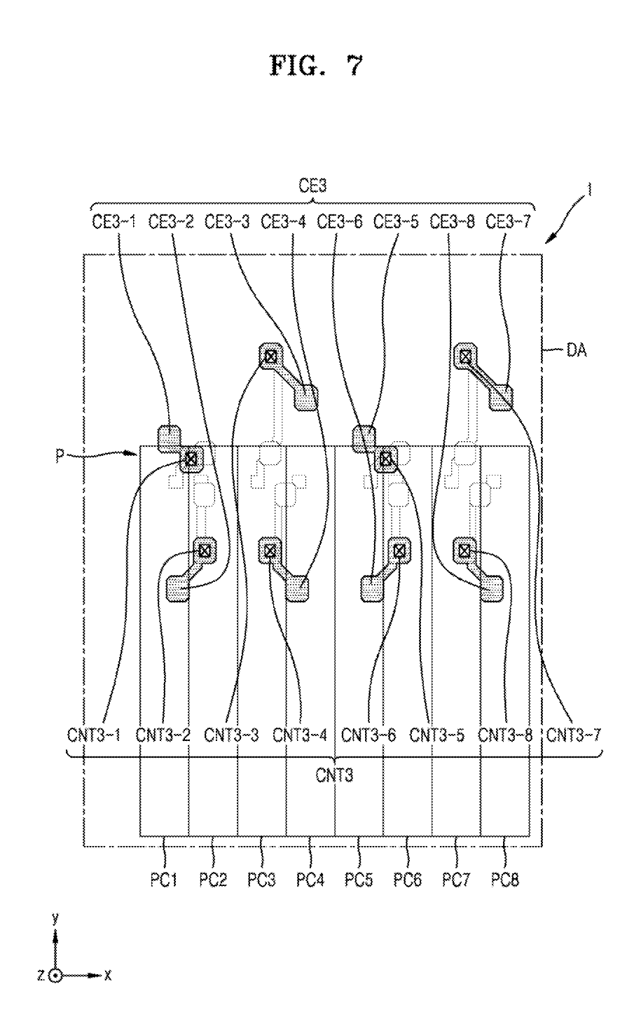

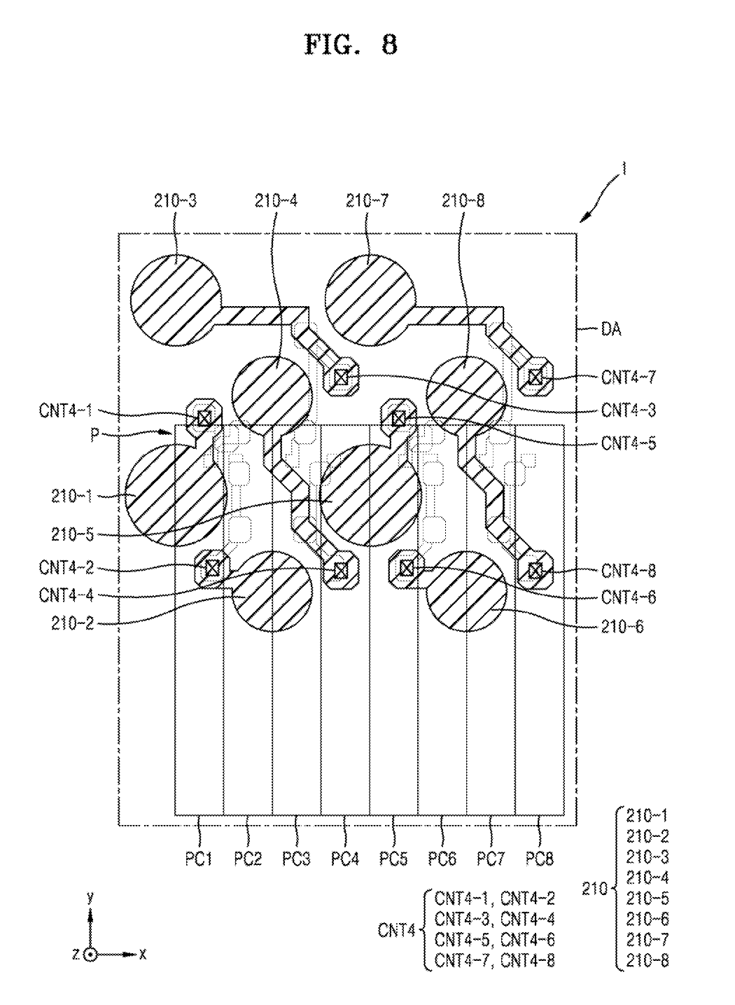

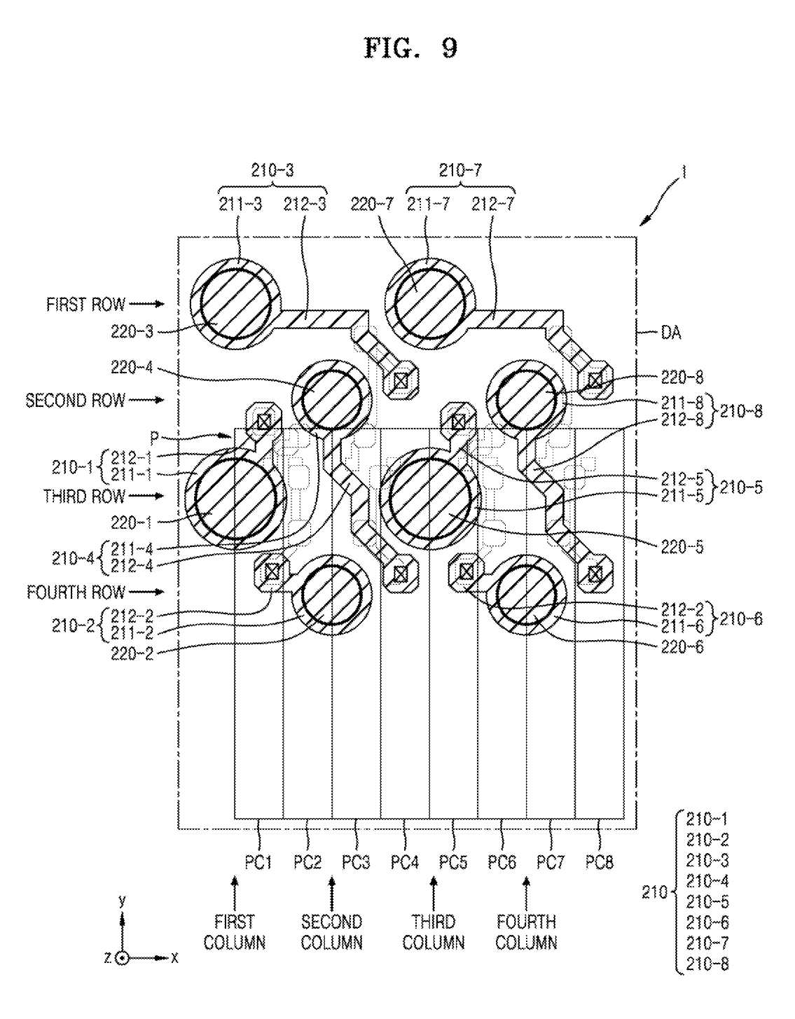

FIGS. 5 - 9 are plan views schematically illustrating the display device 1 according to an embodiment.

Specifically, FIGS. 5 - 9 are plan views of the display device 1, illustrating components corresponding to a single pixel P in the display area DA.

For convenience of explanation, in FIGS. 5 - 9, only the sub-pixel circuits, the first connection electrode CE1, the second connection electrode CE2, the third connection electrode CE3, the pixel electrodes 210, and the emission layers 220 are shown, and in locations where components overlap, components disposed underneath are shown with lighter lines.

First, referring to FIG. 5, the display device 1 may include first, second, third, fourth, fifth, sixth, seventh, and eighth sub-pixel circuits PC1, PC2, PC3, PC4, PC5, PC6, PC7, and PC8 (herein collectively referred to as “first to eighth sub-pixel circuits PC1 to PC8”). In this case, the first to eighth sub-pixel circuits PC1 to PC8 may overlap the display area DA, but may not overlap the non-display area NDA. The first to eighth sub-pixel circuits PC1 to PC8 may be sequentially disposed in a first direction (e.g., an x-axis direction) on the substrate 100 (see FIG. 4). The first to eighth sub-pixel circuits PC1 to PC8 may each correspond to the sub-pixel circuit PC (see FIG. 3) described with reference to FIG. 3, and the first to eighth sub-pixel circuits PC1 to PC8 may each include a driving transistor and a switching transistor. Because the first to eighth sub-pixel circuits PC1 to PC8 are provided in a structure (vertical fusion pixel (VFP) structure) where the first to eighth sub-pixel circuits PC1 to PC8 are sequentially disposed in the first direction (e.g., the x-axis direction), the space efficiency of the first to eighth sub-pixel circuits PC1 to PC8 may be improved.

As shown in FIG. 5, areas where the first to eighth sub-pixel circuits PC1 to PC8 are respectively disposed in a plan view may be simplified and shown in a rectangular shape. This rectangular shape is actually a simplified representation of a physical layout structure of the first to eighth sub-pixel circuits PC1 to PC8, and may not exactly match the actual shape of the first to eighth sub-pixel circuits PC1 to PC8.

In this case, in a plan view, the first to eighth sub-pixel circuits PC1 to PC8 may each have a rectangular shape in which one side is longer than another side. For example, as shown in FIG. 5, the first to eighth sub-pixel circuits PC1 to PC8 may each have a rectangular shape having a length in the first direction (e.g., the x-axis direction) that is less than a length in a second direction (e.g., a y-axis direction). Because the first to eighth sub-pixel circuits PC1 to PC8 are disposed sequentially in the first direction (e.g., the x-axis direction), an overall shape of the first to eighth sub-pixel circuits PC1 to PC8 may be relatively closer to a square shape compared to individual shapes of the first to eighth sub-pixel circuits PC1 to PC8.

The first insulating layer IL1 (see FIG. 4) may be disposed on the substrate 100 (see FIG. 4) to cover the first to eighth sub-pixel circuits PC1 to PC8. The first insulating layer IL1 (see FIG. 4), which provides electrical insulation, may comprehensively cover the area where the first to eighth sub-pixel circuits PC1 to PC8 are disposed, thereby preventing interference between circuits and protecting the circuits from an external environment. Specifically, the buffer layer 101 (see FIG. 4), the first gate insulating layer 103 (see FIG. 4), the second gate insulating layer 105 (see FIG. 4), the first interlayer insulating layer 107 (see FIG. 4), the third gate insulating layer 109 (see FIG. 4), and the second interlayer insulating layer 111 (see FIG. 4) may cover the first to eighth sub-pixel circuits PC1 to PC8.

The first connection electrode CE1 may be disposed on the first insulating layer IL1 (see FIG. 4) (specifically, the second interlayer insulating layer 111 (see FIG. 4)). The first connection electrode CE1 may be electrically connected to the first to eighth sub-pixel circuits PC1 to PC8. The first connection electrode CE1 may come into contact with the first to eighth sub-pixel circuits PC1 to PC8 through a first contact hole CNT1, which extends through the first insulating layer IL1 (see FIG. 4) (specifically, at least one of the first gate insulating layer 103 (see FIG. 4), the second gate insulating layer 105 (see FIG. 4), the first interlayer insulating layer 107 (see FIG. 4), the third gate insulating layer 109 (see FIG. 4), and the second interlayer insulating layer 111 (see FIG. 4), hereinafter referred to as "second interlayer insulating layer 111 (see FIG. 4)").

The first connection electrode CE1 may include first-1 to first-8 connection electrodes CE1-1 to CE1-8 corresponding to the first to eighth sub-pixel circuits PC1 to PC8, respectively. The first contact hole CNT1 may include first-1 to first-8 contact holes CNT1-1 to CNT1-8 corresponding to the first to eighth sub-pixel circuits PC1 to PC8, respectively.

The first-1 connection electrode CE1-1 may be at a position where at least a portion of the first-1 connection electrode CE1-1 overlaps the first sub-pixel circuit PC1. The first-1 contact hole CNT1-1 may extend through the first insulating layer IL1 (see FIG. 4) (specifically, the second interlayer insulating layer 111 (see FIG. 4), etc.) at a position overlapping each of the first sub-pixel circuit PC1 and the first-1 connection electrode CE1-1. The first-1 connection electrode CE1-1 may come into contact with the first sub-pixel circuit PC1 through the first-1 contact hole CNT1-1.

The first-2 connection electrode CE1-2 may be at a position where at least a portion of the first-2 connection electrode CE1-2 overlaps the second sub-pixel circuit PC2. The first-2 contact hole CNT1-2 may extend through the first insulating layer IL1 (see FIG. 4) (specifically, the second interlayer insulating layer 111 (see FIG. 4), etc.) at a position overlapping each of the second sub-pixel circuit PC2 and the first-2 connection electrode CE1-2. The first-2 connection electrode CE1-2 may come into contact with the second sub-pixel circuit PC2 through the first-2 contact hole CNT1-2.

The first-3 connection electrode CE1-3 may be at a position where at least a portion of the first-3 connection electrode CE1-3 overlaps the third sub-pixel circuit PC3. The first-3 contact hole CNT1-3 may extend through the first insulating layer IL1 (see FIG. 4) (specifically, the second interlayer insulating layer 111 (see FIG. 4), etc.) at a position overlapping each of the third sub-pixel circuit PC3 and the first-3 connection electrode CE1-3. The first-3 connection electrode CE1-3 maycome into contact with the third sub-pixel circuit PC3 through the first-3 contact hole CNT1-3.

The first-4 connection electrode CE1-4 may be at a position where at least a portion of the first-4 connection electrode CE1-4 overlaps the fourth sub-pixel circuit PC4. The first-4 contact hole CNT1-4 may extend through the first insulating layer IL1 (see FIG. 4) (specifically, the second interlayer insulating layer 111 (see FIG. 4), etc.) at a position overlapping each of the fourth sub-pixel circuit PC4 and the first-4 connection electrode CE1-4. The first-4 connection electrode CE1-4 may come into contact with the fourth sub-pixel circuit PC4 through the first-4 contact hole CNT1-4.

The first-5 connection electrode CE1-5 may be at a position where at least a portion of the first-5 connection electrode CE1-5 overlaps the fifth sub-pixel circuit PC5. The first-5 contact hole CNT1-5 may extend through the first insulating layer IL1 (see FIG. 4) (specifically, the second interlayer insulating layer 111 (see FIG. 4), etc.) at a position overlapping each of the fifth sub-pixel circuit PC5 and the first-5 connection electrode CE1-5. CE1 first-5 connection electrode CE1-5 may come into contact with the fifth sub-pixel circuit PC5 through the first-5 contact hole CNT1-5.

The first-6 connection electrode CE1-6 may be at a position where at least a portion of the first-6 connection electrode CE1-6 overlaps the sixth sub-pixel circuit PC6. The first-6 contact hole CNT1-6 may extend through the first insulating layer IL1 (see FIG. 4) (specifically, the second interlayer insulating layer 111 (see FIG. 4), etc.) at a position overlapping each of the sixth sub-pixel circuit PC6 and the first-6 connection electrode CE1-6. The first-6 connection electrode CE1-6 may come into contact with the sixth sub-pixel circuit PC6 through the first-6 contact hole CNT1-6.

The first-7 connection electrode CE1-7 may be at a position where at least a portion of the first-7 connection electrode CE1-7 overlaps the seventh sub-pixel circuit PC7. The first-7 contact hole CNT1-7 may extend through the first insulating layer IL1 (see FIG. 4) (specifically, the second interlayer insulating layer 111 (see FIG. 4), etc.) at a position overlapping each of the seventh sub-pixel circuit PC7 and the first-7 connection electrode CE1-7. The first-7 connection electrode CE1-7 may come into contact with the seventh sub-pixel circuit PC7 through the first-7 contact hole CNT1-7.

The first-8 connection electrode CE1-8 may be at a position where at least a portion of the first-8 connection electrode CE1-8 overlaps the eighth sub-pixel circuit PC8. The first-8 contact hole CNT1-8 may extend through the first insulating layer IL1 (see FIG. 4) (specifically, the second interlayer insulating layer 111 (see FIG. 4), etc.) at a position overlapping each of the eighth sub-pixel circuit PC8 and the first-8 connection electrode CE1-8. The first-8 connection electrode CE1-8 may come into contact with the eighth sub-pixel circuit PC8 through the first-8 contact hole CNT1-8.

The shapes of the first-1 to first-8 connection electrodes CE1-1 to CE1-8 may each be designed in various ways considering requirements, such as interference with other wiring and/or signal lines.

Referring to FIG. 6, the first insulating layer IL1 (see FIG. 4) may cover the first connection electrode CE1. Specifically, the first organic insulating layer 113 (see FIG. 4) may be disposed on the second interlayer insulating layer 111 (see FIG. 4) to cover the first connection electrode CE1.

The second connection electrode CE2 may be disposed on the first insulating layer IL1 (see FIG. 4) (specifically, the first organic insulating layer 113 (see FIG. 4)). The second connection electrode CE2 may be electrically connected to the first connection electrode CE1. The second connection electrode CE2 may come into contact with the first connection electrode CE1 through a second contact hole CNT2, which extends through the first insulating layer IL1 (see FIG. 4) (specifically, the first organic insulating layer 113 (see FIG. 4)).

The second connection electrode CE2 may include second-1 to second-8 connection electrodes CE2-1 to CE2-8 corresponding to the first-1 to first-8 connection electrodes CE1-1 to CE1-8, respectively. The second contact hole CNT2 may include second-1 to second-8 contact holes CNT2-1 to CNT2-8 corresponding to the first-1 to first-8 connection electrodes CE1-1 to CE1-8, respectively.

The second-1 connection electrode CE2-1 may be at a position where at least a portion of the second-1 connection electrode CE2-1 overlaps the first-1 connection electrode CE1-1. The second-1 contact hole CNT2-1 may extend through the first insulating layer IL1 (see FIG. 4) (specifically, the first organic insulating layer 113 (see FIG. 4) etc.) at a position overlapping each of the first-1 connection electrode CE1-1 and the second-1 connection electrode CE2-1. The second-1 connection electrode CE2-1 may come into contact with the first-1 connection electrode CE1-1 through the second-1 contact hole CNT2-1.

The second-2 connection electrode CE2-2 may be positioned at a position where at least a portion of the second-2 connection electrode CE2-2 overlaps the first-2 connection electrode CE1-2. The second-2 contact hole CNT2-2 may extend through the first insulating layer IL1 (see FIG. 4) (specifically, the first organic insulating layer 113 (see FIG. 4), etc.) at a position overlapping each of the first-2 connection electrode CE1-2 and the second-2 connection electrode CE2-2. The second-2 connection electrode CE2-2 may come into contact with the first-2 connection electrode CE1-2 through the second-2 contact hole CNT2-2.

The second-3 connection electrode CE2-3 may be positioned at a position where at least a portion of the second-3 connection electrode CE2-3 overlaps the first-3 connection electrode CE1-3. The second-3 contact hole CNT2-3 may extend through the first insulating layer IL1 (see FIG. 4) (specifically, the first organic insulating layer 113 (see FIG. 4), etc.) at a position overlapping each of the first-3 connection electrode CE1-3 and the second-3 connection electrode CE2-3. The second-3 connection electrode CE2-3 may come into contact with the first-3 connection electrode CE1-3 through the second-3 contact hole CNT2-3.

The second-4 connection electrode CE2-4 may be positioned at a position where at least a portion of the second-4 connection electrode CE2-4 overlaps the first-4 connection electrode CE1-4. The second-4 contact hole CNT2-4 may extend through the first insulating layer IL1 (see FIG. 4) (specifically, the first organic insulating layer 113 (see FIG. 4), etc.) at a position overlapping each of the first-4 connection electrode CE1-4 and the second-4 connection electrode CE2-4. The second-4 connection electrode CE2-4 may come into contact with the first-4 connection electrode CE1-4 through the second-4 contact hole CNT2-4.

The second-5 connection electrode CE2-5 may be positioned at a position where at least a portion of the second-5 connection electrode CE2-5 overlaps the first-5 connection electrode CE1-5. The second-5 contact hole CNT2-5 may extend through the first insulating layer IL1 (see FIG. 4) (specifically, the first organic insulating layer 113 (see FIG. 4), etc.) at a position overlapping each of the first-5 connection electrode CE1- 5 and the second-5 connection electrode CE2-5. The second-5 connection electrode CE2-5 may come into contact with the first-5 connection electrode CE1-5 through the second-5 contact hole CNT2-5.

The second-6 connection electrode CE2-6 may be positioned at a position where at least a portion of the second-6 connection electrode CE2-6 overlaps the first-6 connection electrode CE1-6. The second-6 contact hole CNT2-6 may extend through the first insulating layer IL1 (see FIG. 4) (specifically, the first organic insulating layer 113 (see FIG. 4), etc.) at a position overlapping each of the first-6 connection electrode CE1-6 and the second-6 connection electrode CE2-6. The second-6 connection electrode CE2-6 may come into contact with the first-6 connection electrode CE1-6 through the second-6 contact hole CNT2-6.

The second-7 connection electrode CE2-7 may be positioned at a position where at least a portion of the second-7 connection electrode CE2-7 overlaps the first-7 connection electrode CE1-7. The second-7 contact hole CNT2-7 may extend through the first insulating layer IL1 (see FIG. 4) (specifically, the first organic insulating layer 113 (see FIG. 4), etc.) at a position overlapping each of the first-7 connection electrode CE1- 7 and the second-7 connection electrode CE2-7. The second-7 connection electrode CE2-7 may come into contact with the first-7 connection electrode CE1-7 through the second-7 contact hole CNT2-7.

The second-8 connection electrode CE2-8 may be positioned where at least a portion of the second-8 connection electrode CE2-8 overlaps the first-8 connection electrode CE1-8. The second-8 contact hole CNT2-8 may extend through the first insulating layer IL1 (see FIG. 4) (specifically, the first organic insulating layer 113 (see FIG. 4), etc.) at a position overlapping each of the first-8 connection electrode CE1-8 and the second-8 connection electrode CE2-8. The second-8 connection electrode CE2-8 may come into contact with the first-8 connection electrode CE1-8 through the second-8 contact hole CNT2-8.

The shapes of the second-1 to second-8 connection electrodes CE2-1 to CE2-8 may each be designed in various ways considering requirements, such as interference with other wiring and/or signal lines.

Referring to FIG. 7, the first insulating layer IL1 (see FIG. 4) may cover the second connection electrode CE2. Specifically, the second organic insulating layer 115(see FIG. 4) may be disposed on the first organic insulating layer 113 (see FIG. 4) to cover the second connection electrode CE2.

The third connection electrode CE3 may be disposed on the first insulating layer IL1 (see FIG. 4) (specifically, the second organic insulating layer 115 (see FIG. 4)). The third connection electrode CE3 may be electrically connected to the second connection electrode CE2. The third connection electrode CE3 may come into contact with the second connection electrode CE2 through a third contact hole CNT3, which extends through the first insulating layer IL1 (see FIG. 4) (specifically, the second organic insulating layer 115 (see FIG. 4)).

The third connection electrode CE3 may include third-1 to third-8 connection electrodes CE3-1 to CE3-8 corresponding to the second-1 to second-8 connection electrodes CE2-1 to CE2-8, respectively. The third contact hole CNT3 may include third-1 to third-8 contact holes CNT3-1 to CNT3-8 corresponding to the second-1 to second-8 connection electrodes CE2-1 to CE2-8, respectively.

The third-1 connection electrode CE3-1 may be at a position where at least a portion of the third-1 connection electrode CE3-1 overlaps the second-1 connection electrode CE2-1. The third-1 contact hole CNT3-1 may extend through the first insulating layer IL1 (see FIG. 4) (specifically, the second organic insulating layer 115 (see FIG. 4), etc.) at a position overlapping each of the second-1 connection electrode CE2-1 and the third-1 connection electrode CE3-1. The third-1 connection electrode CE3-1 maycome into contact with the second-1 connection electrode CE2-1 through the third-1 contact hole CNT3-1.

The third-2 connection electrode CE3-2 may be positioned where at least a portion of the third-2 connection electrode CE3-2 overlaps the second-2 connection electrode CE2-2. The third-2 contact hole CNT3-2 may extend through the first insulating layer IL1 (see FIG. 4) (specifically, the second organic insulating layer 115 (see FIG. 4), etc.) at a position overlapping each of the second-2 connection electrode CE2-2 and the third-2 connection electrode CE3-2. The third-2 connection electrode CE3-2 maycome into contact with the second-2 connection electrode CE2-2 through the third-2 contact hole CNT3-2.

The third-3 connection electrode CE3-3 may be at a position where at least a portion of the third-3 connection electrode CE3-3 overlaps the second-3 connection electrode CE2-3. The third-3 contact hole CNT3-3 may extend through the first insulating layer IL1 (see FIG. 4) (specifically, the second organic insulating layer 115 (see FIG. 4), etc.) at a position overlapping each of the second-3 connection electrode CE2-3 and the third-3 connection electrode CE3-3. The third-3 connection electrode CE3-3 may come into contact with the second-3 connection electrode CE2-3 through the third-3 contact hole CNT3-3.

The third-4 connection electrode CE3-4 may be at a position where at least a portion of the third-4 connection electrode CE3-4 overlaps the second-4 connection electrode CE2-4. The third-4 contact hole CNT3-4 may extend through the first insulating layer IL1 (see FIG. 4) (specifically, the second organic insulating layer 115 (see FIG. 4), etc.) at a position overlapping each of the second-4 connection electrode CE2-4 and the third-4 connection electrode CE3-4. The third-4 connection electrode CE3-4 may come into contact with the second-4 connection electrode CE2-4 through the third-4 contact hole CNT3-4.

The third-5 connection electrode CE3-5 may be at a position where at least a portion of the third-5 connection electrode CE3-5 overlaps the second-5 connection electrode CE2-5. The third-5 contact hole CNT3-5 may extend through the first insulating layer IL1 (see FIG. 4) (specifically, the second organic insulating layer 115 (see FIG. 4), etc.) at a position overlapping each of the second-5 connection electrode CE2-5 and the third-5 connection electrode CE3-5. The third-5 connection electrode CE3-5 may come into contact with the second-5 connection electrode CE2-5 through the third-5 contact hole CNT3-5.

The third-6 connection electrode CE3-6 may be at a position where at least a portion of the third-6 connection electrode CE3-6 overlaps the second-6 connection electrode CE2-6. The third-6 contact hole CNT3-6 may extend through the first insulating layer IL1 (see FIG. 4) (specifically, the second organic insulating layer 115 (see FIG. 4), etc.) at a position overlapping each of the second-6 connection electrode CE2-6 and the third-6 connection electrode CE3-6. The third-6 connection electrode CE3-6 may come into contact with the second-6 connection electrode CE2-6 through the third-6 contact hole CNT3-6.

The third-7 connection electrode CE3-7 may be at a position where at least a portion of the third-7 connection electrode CE3-7 overlaps the second-7 connection electrode CE2-7. The third-7 contact hole CNT3-7 may extend through the first insulating layer IL1 (see FIG. 4) (specifically, the second organic insulating layer 115 (see FIG. 4), etc.) at a position overlapping each of the second-7 connection electrode CE2-7 and the third-7 connection electrode CE3-7. The third-7 connection electrode CE3-7 may come into contact with the second-7 connection electrode CE2-7 through the third-7 contact hole CNT3-7.

The third-8 connection electrode CE3-8 may be at a position where at least a portion of the third-8 connection electrode CE3-8 overlaps the second-8 connection electrode CE2-8. The third-8 contact hole CNT3-8 may extend through the first insulating layer IL1 (see FIG. 4) (specifically, the second organic insulating layer 115 (see FIG. 4), etc.) at a position overlapping each of the second-8 connection electrode CE2-8 and the third-8 connection electrode CE3-8. The third-8 connection electrode CE3-8 may come into contact with the second-8 connection electrode CE2-8 through the third-8 contact hole (CNT3-8).

The shapes of the third-1 to third-8 connection electrodes CE3-1 to CE3-8 may each be designed in various ways considering requirements, such as interference with other wiring and/or signal lines.

Referring to FIG. 8, the first insulating layer IL1 (see FIG. 4) may cover the third connection electrode CE3. Specifically, the third organic insulating layer 117 (see FIG. 4) may be disposed on the second organic insulating layer 115 (see FIG. 4) to cover the third connection electrode CE3.

The pixel electrodes 210 may be spaced apart from each other on the first insulating layer IL1 (see FIG. 4) (specifically, the third organic insulating layer 117 (see FIG. 4)). The pixel electrodes 210 may be electrically connected to the third connection electrode CE3. The pixel electrodes 210 may come into contact with the third connection electrode CE3 through a fourth contact hole CNT4, which extends through at least part of the first insulating layer IL1 (see FIG. 4), such as the third organic insulating layer 117 (see FIG. 4)).

The pixel electrodes 210 may include first to eighth pixel electrodes 210-1 to 210-8 corresponding to the third-1 to third-8 connection electrodes CE3-1 to CE3-8, respectively. The fourth contact hole CNT4 may include fourth-1 to fourth-8 contact holes CNT4-1 to CNT4-8 corresponding to the third-1 to third-8 connection electrodes CE3-1 to CE3-8, respectively. In this structure, the first to eighth sub-pixel circuits PC1 to PC8 may be electrically connected to any one of the pixel electrodes 210.

The first pixel electrode 210-1 may be at a position where at least a portion of the first pixel electrode 210-1 overlaps the third-1 connection electrode CE3-1. The fourth-1 contact hole CNT4-1 may extend through the first insulating layer IL1 (see FIG. 4) (specifically, the third organic insulating layer 117 (see FIG. 4), etc.) at a position overlapping each of the third-1 connection electrode CE3-1 and the first pixel electrode 210-1. The first pixel electrode 210-1 may come into contact with the third-1 connection electrode CE3-1 through the fourth-1 contact hole CNT4-1.

The second pixel electrode 210-2 may be at a position where at least a portion of the second pixel electrode 210-2 overlaps the third-2 connection electrode CE3-2. The fourth-2 contact hole CNT4-2 may extend through the first insulating layer IL1 (see FIG. 4) (specifically, the third organic insulating layer 117 (see FIG. 4), etc.) at a position overlapping each of the third-2 connection electrode CE3-2 and the second pixel electrode 210-2. The second pixel electrode 210-2 may come into contact with the third-2 connection electrode CE3-2 through the fourth-2 contact hole CNT4-2.

The third pixel electrode 210-3 may be at a position where at least a portion of the third pixel electrode 210-3 overlaps the third-3 connection electrode CE3-3. The fourth-3 contact hole CNT4-3 may extend through the first insulating layer IL1 (see FIG. 4) (specifically, the third organic insulating layer 117 (see FIG. 4), etc.) at a position overlapping each of the third-3 connection electrode CE3-3 and the third pixel electrode 210-3. The third pixel electrode 210-3 may come into contact with the third-3 connection electrode CE3-3 through the fourth-3 contact hole CNT4-3.

The fourth pixel electrode 210-4 may be at a position where at least a portion of the fourth pixel electrode 210-4 overlaps the third-4 connection electrode CE3-4. The fourth-4 contact hole CNT4-4 may extend through the first insulating layer IL1 (see FIG. 4) (specifically, the third organic insulating layer 117 (see FIG. 4), etc.) at a position overlapping each of the third-4 connection electrode CE3-4 and the fourth pixel electrode 210-4. The fourth pixel electrode 210-4 may come into contact with the third-4 connection electrode CE3-4 through the fourth-4 contact hole CNT4-4.

The fifth pixel electrode 210-5 may be at a position where at least a portion overlaps the third-5 connection electrode CE3-5. The fourth-5 contact hole CNT4-5 may extend through the first insulating layer IL1 (see FIG. 4) (specifically, the third organic insulating layer 117 (see FIG. 4), etc.) at a position overlapping each of the third-5 connection electrode CE3-5 and the fifth pixel electrode 210-5. The fifth pixel electrode 210-5 may come into contact with the third-5 connection electrode CE3-5 through the fourth-5 contact hole CNT4-5.

The sixth pixel electrode 210-6 may be at a position where at least a portion of the sixth pixel electrode 210-6 overlaps the third-6 connection electrode CE3-6. The fourth-6 contact hole CNT4-6 may extend through the first insulating layer IL1 (see FIG. 4) (specifically, the third organic insulating layer 117 (see FIG. 4), etc.) at a position overlapping each of the third-6 connection electrode CE3-6 and the sixth pixel electrode 210-6. The sixth pixel electrode 210-6 may come into contact with the third-6 connection electrode CE3-6 through the fourth-6 contact hole CNT4-6.

The seventh pixel electrode 210-7 may be at a position where at least a portion of the seventh pixel electrode 210-7 overlaps the third-7 connection electrode CE3-7. The fourth-7 contact hole CNT4-7 may extend through the first insulating layer IL1 (see FIG. 4) (specifically, the third organic insulating layer 117 (see FIG. 4), etc.) at a position overlapping each of the third-7 connection electrode CE3-7 and the seventh pixel electrode 210-7. The seventh pixel electrode 210-7 may come into contact with the third-7 connection electrode CE3-7 through the fourth-7 contact hole CNT4-7.

The eighth pixel electrode 210-8 may be at a position where at least a portion of the eighth pixel electrode 210-8 overlaps the third-8 connection electrode CE3-8. The fourth-8 contact hole CNT4-8 may extend through the first insulating layer IL1 (see FIG. 4) (specifically, the third organic insulating layer 117 (see FIG. 4), etc.) at a position overlapping each of the third-8 connection electrode CE3-8 and the eighth pixel electrode 210-8. The eighth pixel electrode 210-8 may come into contact with the third-8 connection electrode CE3-8 through the fourth-8 contact hole CNT4-8.

The shapes of the first to eighth pixel electrodes 210-1 to 210-8 may each be designed in various ways considering requirements, such as interference with other wiring and/or signal lines.

Referring to FIGS. 8 and 9, the emission layers 220 may be disposed on the pixel electrodes 210, respectively, so as to be spaced apart from each other. The emission layer 220 may be disposed on the pixel electrode 210 in a one-to-one manner. The emission layers 220 may be in contact with the pixel electrodes 210 and electrically connected to the pixel electrodes 210.

The first sub-pixel circuit PC1 and the seventh sub-pixel circuit PC7 may receive data signals for light of a same color (e.g., red). The second sub-pixel circuit PC2, the fourth sub-pixel circuit PC4, the sixth sub-pixel circuit PC6, and the eighth sub-pixel circuit PC8 may receive data signals for light of a same color (e.g., green). The third sub-pixel circuit PC3 and the fifth sub-pixel circuit PC5 may receive data signals for light of a same color (e.g., blue). In this structure, the first sub-pixel circuit PC1, the second sub-pixel circuit PC2, and the third sub-pixel circuit PC3 may receive data signals for light of different colors from each other.

The emission layers 220 may include first to eighth emission layers 220-1 to 220-8 corresponding to the first to eighth pixel electrodes 210-1 to 210-8, respectively. The emission layers 220 may be disposed in a PenTile structure. For example, the first emission layer 220-1 may emit red light, the second emission layer 220-2 may emit green light, the third emission layer 220-3 may emit blue light, the fourth emission layer 220-4 may emit green light, the fifth emission layer 220-5 may emit blue light, the sixth emission layer 220-6 may emit green light, the seventh emission layer 220-7 may emit red light, and the eighth emission layer 220-8 may emit green light. When the emission layers 220, which emit green light with relatively good visibility, are disposed at a high density, the overall color balance of the display device 1 may be maintained while improving energy efficiency.

Imaginary first, second, third, and fourth rows may be defined, which extend in the first direction (e.g., the x-axis direction) and are spaced apart from each other in the second direction (e.g., the y-axis direction). In addition, imaginary first, second, third, and fourth columns may be defined, which extend in the second direction (e.g., the y-axis direction) and are spaced apart from each other in the first direction (e.g., the x-axis direction).

As shown in FIG. 9, the third emission layer 220-3 and the seventh emission layer 220-7 may be spaced apart from each other in the first row. In the second row, the fourth emission layer 220-4 and the eighth emission layer 220-8 may be spaced apart from each other. In the third row, the first emission layer 220-1 and the fifth emission layer 220-5 may be spaced apart from each other. In the fourth row, the second emission layer 220-2 and the sixth emission layer 220-6 may be spaced apart from each other.

In addition, in the first row, the third emission layer 220-3 and the first emission layer 220-1 may be spaced apart from each other. In the second row, the fourth emission layer 220-4 and the second emission layer 220-2 may be spaced apart from each other. In the third row, the seventh emission layer 220-7 and the fifth emission layer 220-5 may be spaced apart from each other. In the fourth row, the eighth emission layer 220-8 and the sixth emission layer 220-6 may be spaced apart from each other.

In FIG. 9, the shapes of the emission layers 220 are circular in a plan view. However, this is only an example, and the shapes of the emission layers 220 may vary.

In this structure, the first pixel electrode 210-1 may include a first-1 electrode portion 211-1 and a first-2 electrode portion 212-1. The first-1 electrode portion 211-1 may be disposed to overlap the first emission layer 220-1 and may be in contact with the first emission layer 220-1. The first-1 electrode portion 211-1 may be provided in a shape corresponding to the first emission layer 220-1. The first-2 electrode portion 212-1 may connect the first-1 electrode portion 211-1 to the fourth-1 contact hole CNT4-1.

The second pixel electrode 210-2 may include a second-1 electrode portion 211-2 and a second-2 electrode portion 212-2. The second-1 electrode portion 211-2 may be disposed to overlap the second emission layer 220-2 and may be in contact with the second emission layer 220-2. The second-1 electrode portion 211-2 may be provided in a shape corresponding to the second emission layer 220-2. The second-2 electrode portion 212-2 may connect the second-1 electrode portion 211-2 to the fourth-2 contact hole CNT4-2.

The third pixel electrode 210-3 may include a third-1 electrode portion 211-3 and a third-2 electrode portion 212-3. The third-1 electrode portion 211-3 may be disposed to overlap the third emission layer 220-3 and may be in contact with the third emission layer 220-3. The third-1 electrode portion 211-3 may be provided in a shape corresponding to the third emission layer 220-3. The third-2 electrode portion 212-3 may connect the third-1 electrode portion 211-3 to the fourth-3 contact hole CNT4-3.

The fourth pixel electrode 210-4 may include a fourth-1 electrode portion 211-4 and a fourth-2 electrode portion 212-4. The fourth-1 electrode portion 211-4 may be disposed to overlap the fourth emission layer 220-4 and may be in contact with the fourth emission layer 220-4. The fourth-1 electrode portion 211-4 may be provided in a shape corresponding to the fourth emission layer 220-4. The fourth-2 electrode portion 212-4 may connect the fourth-1 electrode portion 211-4 to the fourth-4 contact hole CNT4-4.

The fifth pixel electrode 210-5 may include a fifth-1 electrode portion 211-5 and a fifth-2 electrode portion 212-5. The fifth-1 electrode portion 211-5 may be disposed to overlap the fifth emission layer 220-5 and may be in contact with the fifth emission layer 220-5. The fifth-1 electrode portion 211-5 may be provided in a shape corresponding to the fifth emission layer 220-5. The fifth-2 electrode portion 212-5 may connect the fifth-1 electrode portion 211-5 to the fourth-5 contact hole CNT4-5.

The sixth pixel electrode 210-6 may include a sixth-1 electrode portion 211-6 and a sixth-2 electrode portion 212-6. The sixth-1 electrode portion 211-6 may be disposed to overlap the sixth emission layer 220-6 and may be in contact with the sixth emission layer 220-6. The sixth-1 electrode portion 211-6 may be provided in a shape corresponding to the sixth emission layer 220-6. The sixth-2 electrode portion 212-6 may connect the sixth-1 electrode portion 211-6 to the fourth-6 contact hole CNT4-6.

The seventh pixel electrode 210-7 may include a seventh-1 electrode portion 211-7 and a seventh-2 electrode portion 212-7. The seventh-1 electrode portion 211-7 may be disposed to overlap the seventh emission layer 220-7 and may be in contact with the seventh emission layer 220-7. The seventh-1 electrode portion 211-7 may be provided in a shape corresponding to the seventh emission layer 220-7. The seventh-2 electrode portion 212-7 may connect the seventh-1 electrode portion 211-7 to the fourth-7 contact hole CNT4-7.

The eighth pixel electrode 210-8 may include an eighth-1 electrode portion 211-8 and an eighth-2 electrode portion 212-8. The eighth-1 electrode portion 211-8 may be disposed to overlap the eighth emission layer 220-8 and may be in contact with the eighth emission layer 220-8. The eighth-1 electrode portion 211-8 may be provided in a shape corresponding to the eighth emission layer 220-8. The eighth-2 electrode portion 212-8 may connect the eighth-1 electrode portion 211-8 to the fourth-8 contact hole CNT4-8.

The first-2 electrode portion 212-1, the second-2 electrode portion 212-2, the third-2 electrode portion 212-3, the fourth-2 electrode portion 212-4, the fifth-2 electrode portion 212-5, the sixth-2 electrode portion 212-6, the seventh-2 electrode portion 212-7, and the eighth-2 electrode portion 212-8 may be provided in various shapes to avoid interference with other wiring.

A common electrode 230 (see FIG. 4) may be disposed on the emission layers 220. The common electrode 230 (see FIG. 4) may overlap each of the first to eighth sub-pixel circuits PC1 to PC8.

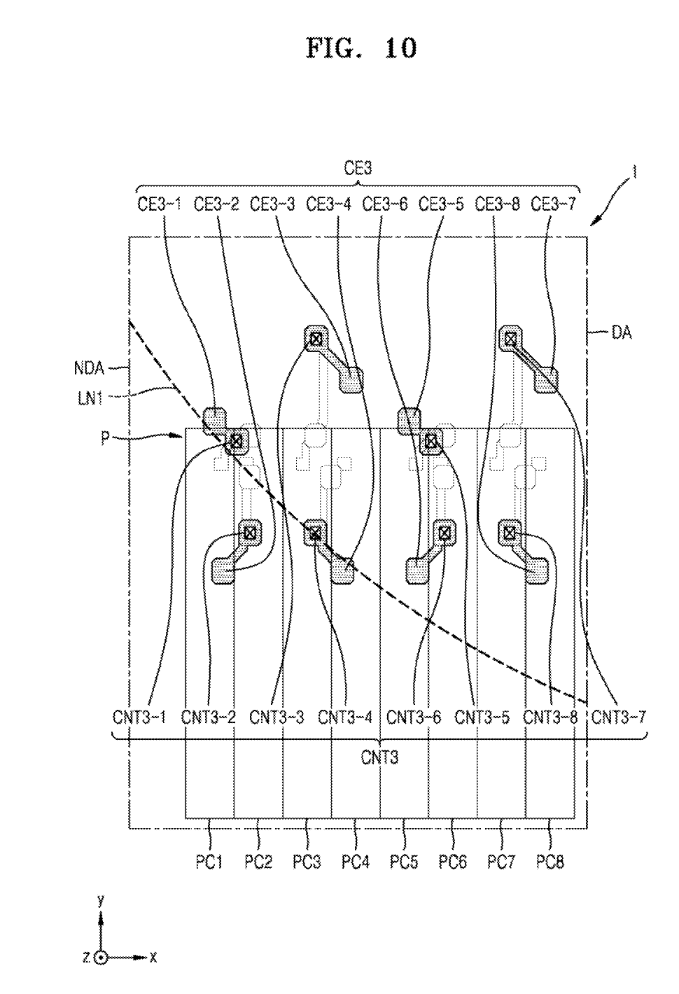

FIGS. 10 - 12 are plan views schematically illustrating the display device 1 according to an embodiment.

Specifically, FIGS. 10 - 12 are plan views of the display device 1 showing components corresponding to one pixel P at a boundary position between the display area DA and the non-display area NDA.

In FIGS. 10 - 12, the same reference numerals as those in FIGS. 5 - 9 indicate the same elements, and the redundant description thereof is omitted.

For convenience of explanation, in FIGS. 10 - 12, only the sub-pixel circuits, the first connection electrode CE1, the second connection electrode CE2, the third connection electrode CE3, the pixel electrodes 210, and the emission layers 220 are shown, and in locations where components overlap, components disposed underneath are shown with lighter lines.

Referring to FIG. 10, the display device 1 may include the first to eighth sub-pixel circuits PC1 to PC8. Each of the first and second sub-pixel circuits PC1 and PC2 may have at least a portion overlapping the non-display area NDA. Each of the third to eighth sub-pixel circuits PC3 to PC8 may have at least a portion overlapping the display area DA. For example, each of the first to eighth sub-pixel circuits PC1 to PC8 may overlap each of the non-display area NDA and the display area DA.

In a plan view, the boundary between the display area DA and the non-display area NDA may be defined as a first line LN1. As shown in FIG. 10, at least a portion of the first line LN1 may be provided in a curved shape. For example, the first line LN1 may be provided in a convex shape directed from the display area DA toward the non-display area NDA.

The configuration of the first to eighth sub-pixel circuits PC1 to PC8 shown in FIG. 10, the first connection electrode CE1 (see FIG. 5), the second connection electrode CE2 (see FIG. 6), the third connection electrode CE3 (see FIG. 7), and the third contact hole CNT3 (see FIG. 7) shown in FIG. 10 is described above with reference to FIGS. 5 - 7, and thus a detailed description thereof will be omitted.

Referring to FIGS. 10 and 11, the first insulating layer IL1 (see FIG. 4) may cover the third connection electrode CE3. Specifically, the third organic insulating layer 117 (see FIG. 4) may be disposed on the second organic insulating layer 115 (see FIG. 4) to cover the third connection electrode CE3.

The pixel electrodes 210 may be spaced apart from each other on the first insulating layer IL1 (see FIG. 4) (specifically, the third organic insulating layer 117 (see FIG. 4)). The pixel electrodes 210 may be electrically connected to the third connection electrode CE3. The pixel electrodes 210 may come into contact with the third connection electrode CE3 through the fourth contact hole CNT4, which extends through the first insulating layer IL1 (see FIG. 4) (specifically, the third organic insulating layer 117 (see FIG. 4)).

The pixel electrodes 210 may include the third to eighth pixel electrodes 210-3 to 210-8 corresponding to the third-3 to third-8 connection electrodes CE3-3 to CE3-8, respectively. The fourth contact hole CNT4 may include the fourth-3 to fourth-8 contact holes CNT4-3 to CNT4-8 corresponding to the third-3 to third-8 connection electrodes CE3-3 to CE3-8, respectively. In this structure, the third to eighth sub-pixel circuits PC3 to PC8 may be electrically connected to any one of the pixel electrodes 210.

The third pixel electrode 210-3 may come into contact with the third-3 connection electrode CE3-3 through the fourth-3 contact hole CNT4-3, the fourth pixel electrode 210-4 may come into contact with the third-4 connection electrode CE3-4 through the fourth-4 contact hole CNT4-4, the fifth pixel electrode 210-5 may come into contact with the third-5 connection electrode CE3-5 through the fourth-5 contact hole CNT4-5, the sixth pixel electrode 210-6 may come into contact with the third-6 connection electrode CE3-6 through the fourth-6 contact hole CNT4-6, the seventh pixel electrode 210-7 may come into contact with the third-7 connection electrode CE3-7 through the fourth-7 contact hole CNT4-7, and the eighth pixel electrode 210-8 may come into contact with the third-8 connection electrode CE3-8 through the fourth-8 contact hole CNT4-8.

The pixel electrodes 210 may not be electrically connected to the third-1 connection electrode CE3-1 and the third-2 connection electrode CE3-2. Unlike what is described above with reference to FIG. 8, the fourth contact hole CNT4 may not include the fourth-1 contact hole CNT4-1 and the fourth-2 contact hole CNT4-2. An upper surface of the third-1 connection electrode CE3-1 electrically connected to the first sub-pixel circuit PC1 may be sealed by the first insulating layer IL1 (specifically, the third organic insulating layer 117). In addition, an upper surface of the third-2 connection electrode CE3-2 electrically connected to the second sub-pixel circuit PC2 may be sealed by the first insulating layer IL1 (specifically, the third organic insulating layer 117). In this structure, the first and second subpixel circuits PC1 and PC2 may not be electrically connected to each of the pixel electrodes 210.

Referring to FIGS. 11 and 12, the emission layers 220 may be disposed on the pixel electrodes 210, respectively, so as to be spaced apart from each other. The emission layer 220 may be disposed on the pixel electrode 210 in a one-to-one manner. The emission layers 220 may be in contact with the pixel electrodes 210 and electrically connected to the pixel electrodes 210. As described above, the pixel electrodes 210 may not be connected to either the first sub-pixel circuit PC1 or the second sub-pixel circuit PC2. The first sub-pixel circuit PC1 and the second sub-pixel circuit PC2 may be electrically isolated from the pixel electrodes 210. Accordingly, the emission layers 220 may not be connected to each of the first sub-pixel circuit PC1 and the second sub-pixel circuit PC2, either.

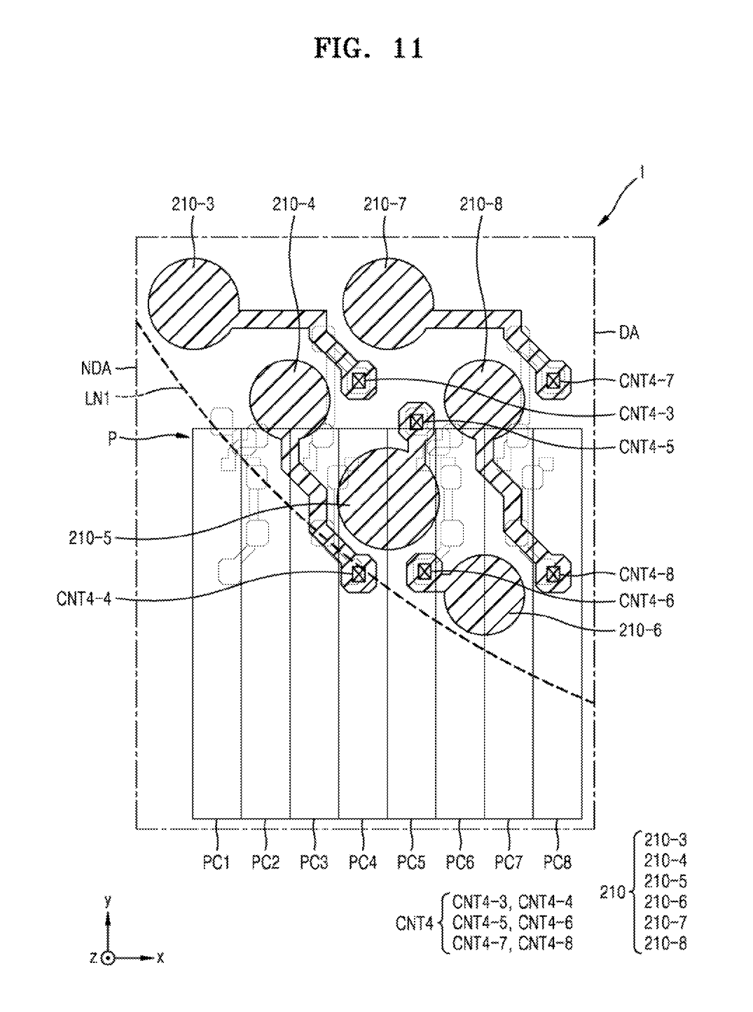

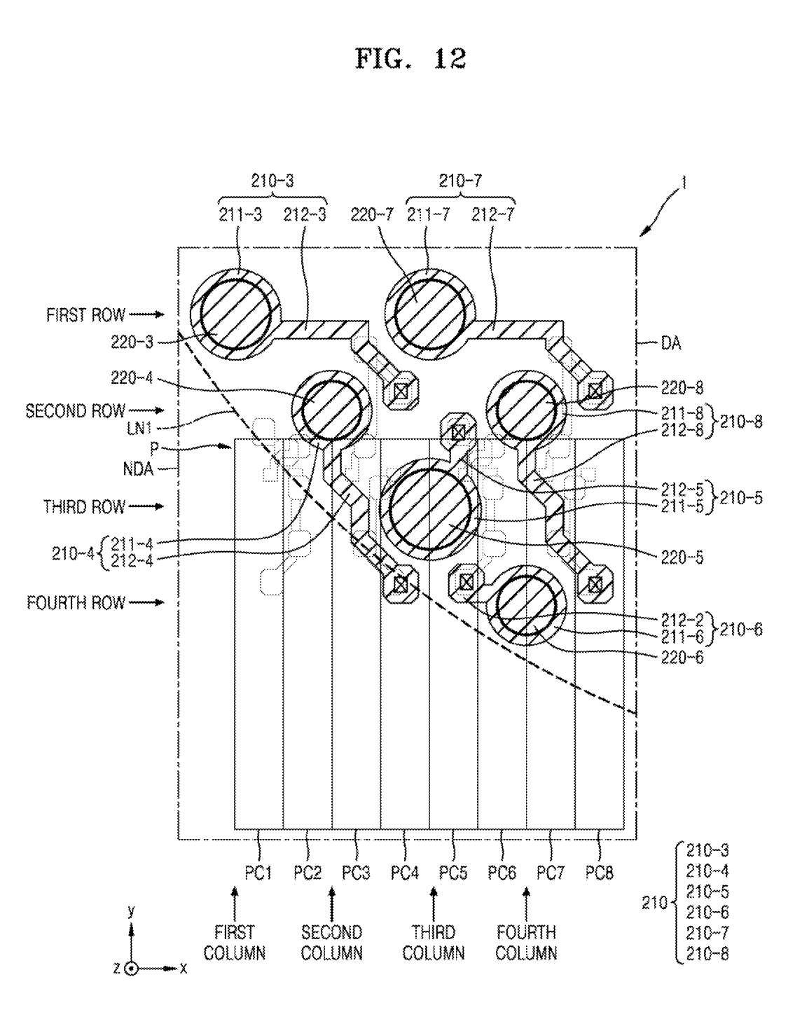

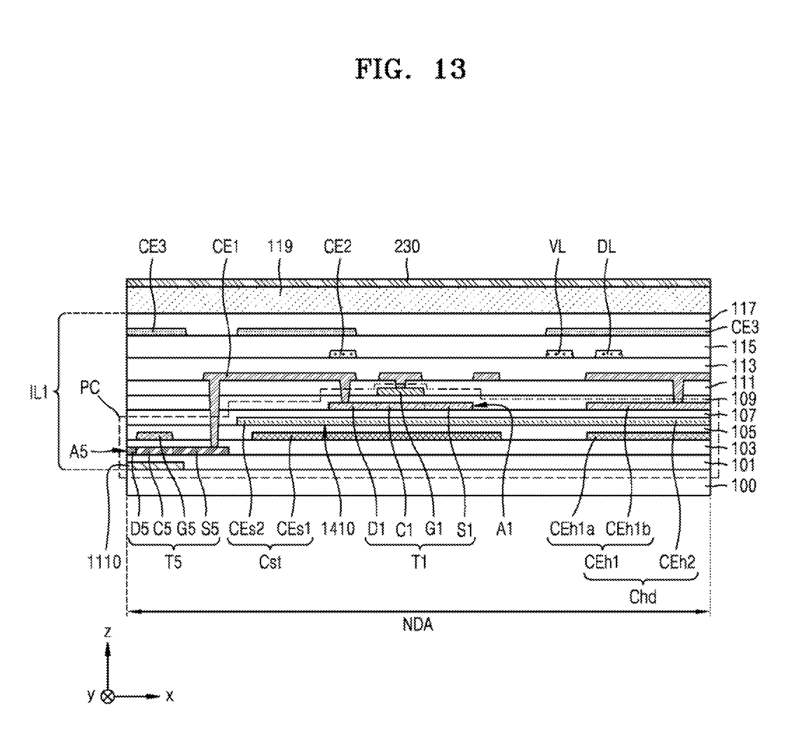

FIG. 13 is a cross-sectional view schematically illustrating the display device 1 according to an embodiment.

Specifically, FIG. 131 is a cross-sectional view of the display device 1 in the non-display area NDA.

In FIG. 13, the same reference numerals as those in FIG. 4 indicate the same elements, and the redundant description thereof is omitted.

Referring to FIG. 13, the display device 1 may include the sub-pixel circuit PC including transistors and capacitors disposed on the substrate 100, and the first insulating layer IL1 covering the sub-pixel circuit PC. In this case, the sub-pixel circuit PC may be any one of the first and second sub-pixel circuits PC1 and PC2 described with reference to FIGS. 10 - 12.

The bank layer 119 may be disposed on the third organic insulating layer 117 to cover the third organic insulating layer 117. The pixel electrode 210 (see FIG. 4) and the emission layer 220 (see FIG. 4) may not be disposed in the non-display area NDA. In the non-display area NDA, an opening may not be formed in the bank layer 119. The common electrode 230 may be disposed on the bank layer 119 and may cover the bank layer 119.

The common electrode 230 (see FIG. 4) may be disposed on the emission layers 220. The common electrode 230 (see FIG. 4) may overlap each of the first to eighth sub-pixel circuits PC1 to PC8.

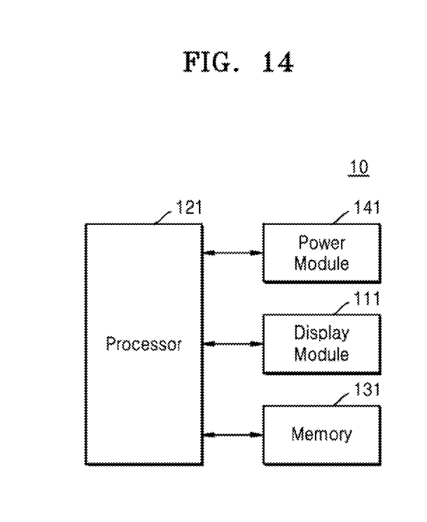

FIG. 14 is a block diagram of an electronic device 10 according to an embodiment.

Referring to FIG. 14, the electronic device 10 according to an embodiment may include a display module 110, a processor 120, a memory 130, and a power module 140.

The processor 120 may include at least one of a central processing unit (CPU), an application processor (AP), a graphics processing unit (GPU), a communication processor (CP), an image signal processor (ISP), and a controller.

Data information necessary for an operation of the processor 120 or display module 110 may be stored in the memory 130. When the processor 120 executes an application stored in the memory 130, image data signals and/or input control signals may be transmitted to the display module 110, and the display module 110 may process the received signals and output image information through a display screen.

The power module 140 may include a power supply module, such as a power adapter or a battery device, and a power conversion module configured to convert power supplied by the power supply module to generate power required for operation of the electronic device 10.

At least one of the components of the electronic device 10 described above may be included in the display device according to the embodiments described above. In addition, some of the individual modules functionally included within a single module may be included within the display device, while other modules may be provided separately from the display device. For example, the display device may include the display module 110, and the processor 120, memory 130, and power module 140 may be provided in the form of other devices within the electronic device 10 other than the display device.

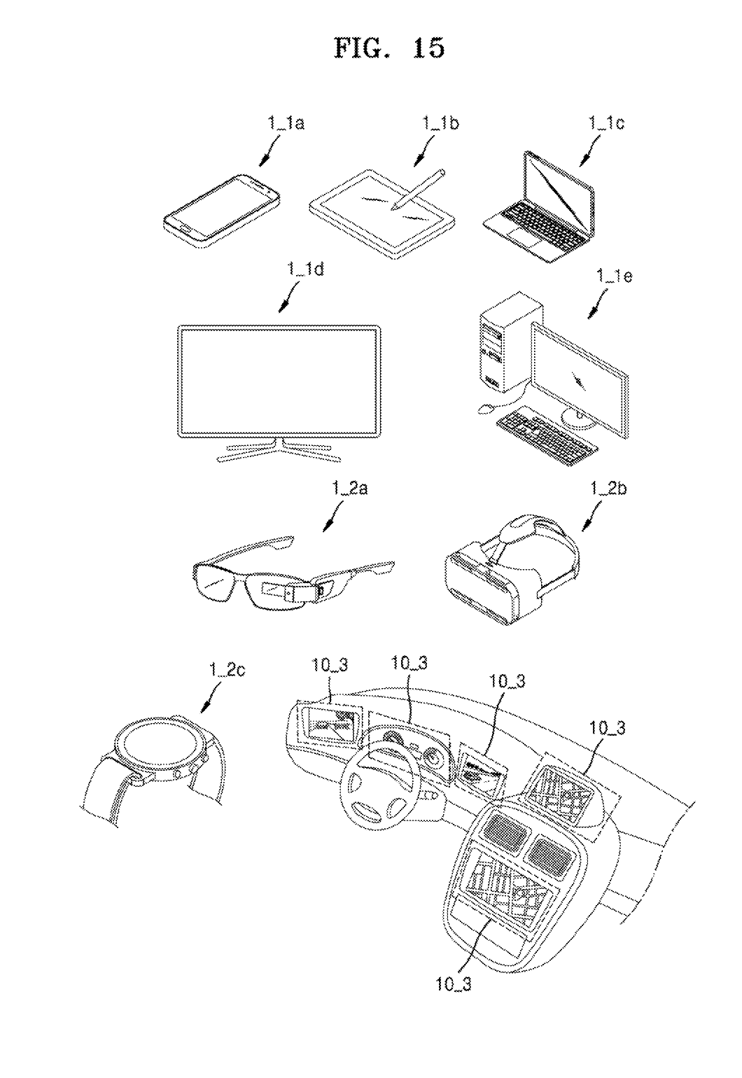

FIG. 15 is schematic diagrams of electronic devices according to various embodiments.

Referring to FIG. 15, various electronic devices to which display devices according to embodiments are applied may include not only image display electronic devices, such as a smartphone 10_1a, a tablet personal computer (PC) 10_1b, a laptop 10_1c, a television (TV) 10_1d, and a desk monitor 10_1e, but also wearable electronic devices including display modules, such as smart glasses 10_2a, a head-mounted display 10_2b, and a smart watch 10_2c, and automotive electronic devices 10_3 including display modules, such as an instrument cluster, center fascia, a center information display (CID) on a dashboard, and room mirror displays.

According to the embodiments, the visibility and quality of the display device can be improved.

The effects of the disclosure are not limited to the effects described above, and other effects not described would be clearly understood by those skilled in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate including a display area and a non-display area;
a first, a second, a third, and a fourth sub-pixel circuit disposed sequentially in a first direction on the substrate and each including a driving transistor and a switching transistor;
a first insulating layer covering the first to fourth sub-pixel circuits;
a plurality of pixel electrodes spaced apart from each other on the first insulating layer; and
a plurality of emission layers disposed on the pixel electrodes, respectively, in the display area,
wherein the first sub-pixel circuit is electrically isolated from the pixel electrodes, and
the fourth sub-pixel circuit is electrically connected to one of the pixel electrodes.

2. The display device of claim 1, wherein at least a portion of the first sub-pixel circuit overlaps the non-display area, and
at least a portion of the fourth sub-pixel circuit overlaps the display area.

3. The display device of claim 1, wherein the second sub-pixel circuit and the fourth sub-pixel circuit are configured to receive data signals for light of a same color.

4. The display device of claim 1, wherein the first sub-pixel circuit, the second sub-pixel circuit, and the third sub-pixel circuit are configured to receive data signals for light of different colors.

5. The display device of claim 1, further comprising a plurality of connection electrodes disposed on the first insulating layer and respectively electrically connected to the first to fourth sub-pixel circuits,
wherein an upper surface of a connection electrode electrically connected to the first sub-pixel circuit is sealed by the first insulating layer, and
a connection electrode electrically connected to the fourth sub-pixel circuit is electrically connected to one of the pixel electrodes.

6. The display device of claim 1, further comprising a common electrode disposed on the emission layers,
wherein the common electrode overlaps each of the first to fourth sub-pixel circuits.

7. The display device of claim 1, further comprising a fifth sub-pixel circuit, a sixth sub-pixel circuit, a seventh sub-pixel circuit, and an eighth sub-pixel circuit disposed sequentially in the first direction from the fourth sub-pixel circuit on the substrate, each including a driving transistor and a switching transistor,
wherein each of the fifth sub-pixel circuit, the sixth sub-pixel circuit, the seventh sub-pixel circuit, and the eighth sub-pixel circuit is electrically connected to a corresponding one of the pixel electrodes and a corresponding one of the emission layers.

8. The display device of claim 7, wherein the first sub-pixel circuit and the seventh sub-pixel circuit are configured to receive data signals for light of a same color,
the second sub-pixel circuit, the fourth sub-pixel circuit, the sixth sub-pixel circuit, and the eighth sub-pixel circuit are configured to receive data signals for light of a same color,
the third sub-pixel circuit and the fifth sub-pixel circuit are configured to receive data signals for light of a same color, and
the first sub-pixel circuit, the second sub-pixel circuit, and the third sub-pixel circuit are configured to receive data signals for light of different colors.

9. The display device of claim 7, wherein emission layers respectively electrically connected to the first, second, third, fourth, fifth, sixth, seventh, and eighth sub-pixel circuits are disposed in a PenTile structure.

10. The display device of claim 1, wherein, in a plan view, at least a portion of a boundary line between the display area and the non-display area has a curved shape.

11. An electronic device comprising:
a substrate including a display area and a non-display area;
a first, a second, a third, a fourth, a fifth, a sixth, a seventh, and an eighth sub-pixel circuit disposed sequentially in a first direction on the substrate and each including a driving transistor and a switching transistor;
a first insulating layer covering the first, the second, the third, the fourth, the fifth, the sixth, the seventh, and the eighth sub-pixel circuits;
a plurality of pixel electrodes spaced apart from each other on the first insulating layer; and
a plurality of emission layers disposed on the pixel electrodes, respectively, in the display area,
wherein the first sub-pixel circuit is electrically isolated from each of the pixel electrodes,
the eighth sub-pixel circuit is electrically connected to one of the pixel electrodes, and
the second sub-pixel circuit, the fourth sub-pixel circuit, the sixth sub-pixel circuit, and the eighth sub-pixel circuit are configured to receive data signals for light of a same color.

12. The electronic device of claim 11, wherein each of the second sub-pixel circuit, the fourth sub-pixel circuit, the sixth sub-pixel circuit, and the eighth sub-pixel circuit is configured to receive a data signal for red light.

13. The electronic device of claim 11, wherein the first sub-pixel circuit and the seventh sub-pixel circuit are configured to receive data signals for light of a same color, and
the third sub-pixel circuit and the fifth sub-pixel circuit are configured to receive data signals for light of a same color.

14. The electronic device of claim 13, wherein each of the first sub-pixel circuit and the seventh sub-pixel circuit is configured to receive a data signal for red light, and
each of the third sub-pixel circuit and the fifth sub-pixel circuit is configured to receive a data signal for blue light.

15. The electronic device of claim 11, wherein the first sub-pixel circuit, the second sub-pixel circuit, and the third sub-pixel circuit are configured to receive data signals for light of different colors.

16. The electronic device of claim 11, wherein emission layers respectively electrically connected to the first, second, third, fourth, fifth, sixth, seventh, and eighth sub-pixel circuits are disposed in a PenTile structure.

17. The electronic device of claim 11, wherein at least a portion of the first sub-pixel circuit overlaps the non-display area, and
at least a portion of the eighth sub-pixel circuit overlaps the display area.

18. The electronic device of claim 11, further comprising a plurality of connection electrodes disposed on the first insulating layer and respectively electrically connected to the first, the second, the third, the fourth, the fifth, the sixth, the seventh, and the eighth sub-pixel circuits.

19. The electronic device of claim 18, wherein an upper surface of a connection electrode electrically connected to the sub-pixel circuit is sealed by the first insulating layer, and
a connection electrode electrically connected to the eighth sub-pixel circuit is electrically connected to one of the pixel electrodes.

20. The electronic device of claim 11, wherein, in a plan view, at least a portion of a boundary line between the display area and the non-display area has a curved shape.
